(19) United States
(12) Patent Application Publication
(10) Pub. No.: US 2012/0217049 A1
(43) Pub. Date: Aug. 30, 2012

(54) WIRING BOARD WITH BUILT-IN IMAGING DEVICE

(75) Inventors: Nobuhiro HANAI, Ogaki-shi (JP); Takaya ENDO, Ogaki-shi (JP); Hirofumi FUTAMURA, Ogaki-shi (JP)

(73) Assignee: IBIDEN CO., LTD., Ogaki-shi (JP)

(21) Appl. No.: 13/334,152

(22) Filed: Dec. 22, 2011

Related U.S. Application Data
(60) Provisional application No. 61/447,255, filed on Feb. 28, 2011.

(51) Int. Cl. H05K 1/18

(52) U.S. Cl. 174/260

(57) ABSTRACT

A wiring board with a built-in imaging element including a substrate having an accommodation portion, an imaging device having a light receiver and positioned in the accommodation portion such that the light receiver faces a first surface of the substrate, first insulation layers having an opening portion and formed on the first surface of the substrate such that the light receiver is exposed from the opening portion, and second insulation layers formed on a second surface of the substrate. The first insulation layers include a first insulation layer, the second insulation layers include a second insulation layer, the second insulation layer is positioned at a predetermined tier and has a thermal expansion coefficient which is set lower than that of the first insulation layer at a predetermined tier such that imbalance in thermal expansion and contraction between the first and second insulation layers is substantially offset or mitigated.

### CROSS-REFERENCE TO RELATED APPLICATIONS

The present application is based on and claims the benefit of priority to U.S. Application No. 61/447,255, filed Feb. 28, 2011, the entire contents of which are incorporated herein by reference.

### BACKGROUND OF THE INVENTION

1. Field of the Invention

The present invention relates to a wiring board with a built-in imaging element.

2. Discussion of the Background

Japanese Laid-Open Patent Publication No. 2008-211179 discloses a wiring board with a built-in imaging element. The wiring board has a built-in imaging element and has an opening portion on one side of a light receiver to expose the light receiver. The contents of Japanese Laid-Open Patent Publication No. 2008-211179 are incorporated herein by reference in their entirety in this application.

### SUMMARY OF THE INVENTION

According to one aspect of the present invention, a wiring board with a built-in imaging element includes a substrate having an accommodation portion and a first surface and a second surface on the opposite side of the first surface, an imaging device having a light receiver and positioned in the accommodation portion of the substrate such that the light receiver faces the first surface of the substrate, first insulation layers having an opening portion and formed on the first surface of the substrate such that the light receiver of the imaging device is exposed from the opening portion of the first insulation layers, and second insulation layers formed on the second surface of the substrate. The first insulation layers include a first insulation layer, the second insulation layers include a second insulation layer, the second insulation layer of the second insulation layers is positioned at a predetermined tier counted from the substrate and has a thermal expansion coefficient which is set lower than a thermal expansion coefficient of the first insulation layer of the first insulation layers positioned at a predetermined tier counted from the substrate such that imbalance in thermal expansion and thermal contraction between the first insulation layers and the second insulation layers is substantially offset or mitigated.

According to another aspect of the present invention, a wiring board with a built-in imaging element includes a substrate having an accommodation portion and a first surface and a second surface on the opposite side of the first surface, an imaging device having a light receiver and positioned in the accommodation portion of the substrate such that the light receiver faces the first surface of the substrate, first insulation layers having an opening portion and formed on the first surface of the substrate such that the light receiver of the imaging device is exposed from the opening portion of the first insulation layers, and second insulation layers formed on the second surface of the substrate. The first insulation layers include a first insulation layer, the second insulation layers include a second insulation layer, the second insulation layer of the second insulation layers is positioned at a predetermined tier counted from the substrate and has the thickness which is set less than the thickness of the first insulation layer of the first insulation layers positioned at a predetermined tier counted from the substrate such that imbalance in thermal expansion and thermal contraction between the first insulation layers and the second insulation layers is substantially offset or mitigated.

According to yet another aspect of the present invention, a wiring board with a built-in imaging element includes a substrate having an accommodation portion and a first surface and a second surface on the opposite side of the first surface, an imaging device having a light receiver and positioned in the accommodation portion of the substrate such that the light receiver faces the first surface of the substrate, first insulation layers having an opening portion and formed on the first surface of the substrate such that the light receiver of the imaging device is exposed from the opening portion of the first insulation layers, and second insulation layers formed on the second surface of the substrate. The second insulation layers has the number of layers which is less than the number of layers of the first insulation layers such that imbalance in thermal expansion and thermal contraction between the first insulation layers and the second insulation layers is substantially offset or mitigated.

According to still another aspect of the present invention, a wiring board with a built-in imaging element includes a substrate having an accommodation portion and a first surface and a second surface on the opposite side of the first surface, an imaging device having a light receiver and positioned in the accommodation portion of the substrate such that the light receiver faces the first surface of the substrate, first insulation layers having an opening portion and formed on the first surface of the substrate such that the light receiver of the imaging device is exposed from the opening portion of the first insulation layers, and second insulation layers formed on the second surface of the substrate. The second insulation layers have a thinned portion in a region corresponding to the opening portion of the first insulation layers, and the thinned portion of the second insulation layers has the thickness which is sufficiently thinned such that imbalance in thermal expansion and thermal contraction between the first insulation layers and the second insulation layers is substantially offset or mitigated.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view outlining a wiring board with a built-in imaging element according to a first embodiment of the present invention and an imaging device structured using the wiring board with a built-in imaging element;

FIG. 2 is a plan view of a wiring board with a built-in imaging element according to the first embodiment seen from the Z1-side of FIG. 1;

FIG. 3 is a view to compare dimensions (in particular, the height from the bottom surface to the light receiver) of the imaging device shown in FIG. 1 and of an imaging device relating to a comparative example;

FIG. 4 is a flowchart showing a method for manufacturing a wiring board with a built-in imaging element according to the first embodiment;

FIG. 5 is a view to illustrate a step for forming in a starting substrate an accommodation space (opening portion) for an imaging element in the manufacturing method shown in FIG. 4;

FIG. 6 is a view to illustrate a step for placing a wiring board on a carrier and a step for positioning an imaging element in the opening portion of the wiring board in the manufacturing method shown in FIG. 4;

FIG. 7 is a view to illustrate a first step for building up a first layer (lower layer) in the manufacturing method shown in FIG. 4;

FIG. 8 is a view to illustrate a second step subsequent to the step in FIG. 7; FIG. 9 is a view showing the shape or the like of a plane conductive pattern positioned in the step in FIG. 8;

FIG. 10 is a view to illustrate a step for forming a recessed portion around the opening portion in the manufacturing method shown in FIG. 4;

FIG. 11 is a view to illustrate a step for mounting an electronic component on a wiring board with a built-in imaging element according to an embodiment of the present invention in the manufacturing method shown in FIG. 4;

FIG. 12 is a cross-sectional view outlining a wiring board with a built-in imaging element according to a second embodiment of the present invention and an imaging device structured using the wiring board with a built-in imaging element;

FIG. 13 is a cross-sectional view outlining a wiring board with a built-in imaging element according to a third embodiment of the present invention and an imaging device structured using the wiring board with a built-in imaging element;

FIG. 14 is a plan view of the wiring board with a built-in imaging element according to the third embodiment seen from the Z2-side of FIG. 13;

FIG. 15 is a cross-sectional view showing a first modified example of the wiring board with a built-in imaging element according to the third embodiment;

FIG. 16 is a cross-sectional view showing a second modified example of the wiring board with a built-in imaging element according to the third embodiment;

FIG. 17A is a cross-sectional view outlining a wiring board with a built-in imaging element according to a fourth embodiment of the present invention and an imaging device structured using the wiring board with a built-in imaging element;

FIG. 17B is a plan view seen from the Z2-side of FIG. 17A showing the wiring board with a built-in imaging element according to the fourth embodiment;

FIG. 18A is a cross-sectional view showing a modified example of the wiring board with a built-in imaging element according to the fourth embodiment;

FIG. 18B is a plan view seen from the Z2-side of FIG. 18A showing the wiring board with a built-in imaging element shown in FIG. 18A;

FIG. 19 is a cross-sectional view showing the structure of a sample relating to a simulation;

FIG. 20A is a plan view showing the surface on the first-surface side of the sample shown in FIG. 19;

FIG. 20B is a plan view showing the surface on the second-surface side of the sample shown in FIG. 19;

FIG. 21 is a view showing the amount of warping to be measured in the simulation;

FIG. 22 is a table showing the structure of each sample in a first simulation;

FIG. 23A is a graph showing the amount of warping on the first-surface side of each sample as a result of the first simulation;

FIG. 23B is a graph showing the amount of warping on the second-surface side of each sample as a result of the first simulation;

FIG. 24 is a table showing the structure of each sample in a second simulation;

FIG. 25A is a graph showing the amount of warping on the first-surface side of each sample as a result of the second simulation;

FIG. 25B is a graph showing the amount of warping on the second-surface side of each sample as a result of the second simulation;

FIG. 26 is a table showing the structure of each sample in a third simulation;

FIG. 27 is a graph showing the amount of warping on the first-surface side of each sample as a result of the third simulation;

FIG. 28 is a table showing the structure of each sample in a fourth simulation;

FIG. 29A is a graph showing the amount of warping on the first-surface side of each sample as a result of the fourth simulation;

FIG. 29B is a graph showing the amount of warping on the second-surface side of each sample as a result of the fourth simulation;

FIG. 30A is regarding a wiring board with a built-in imaging element according to an embodiment of the present invention, a view showing an example in which an opening portion in an upper insulation layer has a greater width than an opening portion of a lower insulation layer;

FIG. 30B is regarding a wiring board with a built-in imaging element according to an embodiment of the present invention, a view showing an example in which an opening portion in an upper insulation layer has a smaller width than an opening portion of a lower insulation layer;

FIG. 31 is a view showing an example in which an imaging element having an electrode on one main surface and a light receiver on the other main surface is built into a wiring board with a built-in imaging element according to an embodiment of the present invention;

FIG. 32 is a view showing an example in which a flexible wiring board is electrically connected to a wiring board with a built-in imaging element according to an embodiment of the present invention;

FIG. 33A is regarding a wiring board with a built-in imaging element according to an embodiment of the present invention, a view showing a first alternative example of the shapes of a light receiver of the imaging element, of an opening portion to expose the light receiver, and of an opening portion in the solder resist;

FIG. 33B is regarding a wiring board with a built-in imaging element according to an embodiment of the present invention, a view showing a second alternative example of the shapes of a light receiver of the imaging element, of an opening portion to expose the light receiver, and of an opening portion in the solder resist;

FIG. 34 is a view showing an example in which a wiring board with a built-in imaging element according to an embodiment of the present invention has three or more buildup layers;

FIG. 35 is a view showing an example in which a wiring board with a built-in imaging element according to an embodiment of the present invention is a single-sided wiring board; and

FIG. 36 is a view showing an example in which a wiring board with a built-in imaging element according to an embodiment of the present invention has a sensor surface on both surfaces.

### DETAILED DESCRIPTION OF THE EMBODIMENTS

The embodiments will now be described with reference to the accompanying drawings, wherein like reference numerals designate corresponding or identical elements throughout the various drawings.

In the drawings, arrows (Z1, Z2) each indicate a lamination direction corresponding to a direction along a normal line (or a thickness direction of a wiring board) to main surfaces (upper and lower surfaces) of each layer. On the other hand, arrows (X1, X2) and (Y1, Y2) each indicate a direction perpendicular to a lamination direction (direction parallel to the main surfaces of each layer). The main surfaces of each layer are on the X-Y plane. Also, side surfaces of each layer are on the X-Z plane or the Y-Z plane.

Two main surfaces facing opposite directions of a normal line are referred to as a first surface (the Z1-side surface) and a second surface (the Z2-side surface). Namely, a main surface opposite the first surface is the second surface, and a main surface opposite the second surface is the first surface. On each tier along lamination directions, the side closer to the core is referred to as a lower layer (or inner-layer side), and the side farther from the core is referred to as an upper layer (or outer-layer side). In addition, on the X-Y plane, the side farther from an imaging element is referred to as outside, and the side closer to the imaging element as inside.

A conductive layer may include wiring that forms a conductive circuit (including ground), a pad, a land or the like, or may include a plane pattern that does not form a conductive circuit.

Opening portions include a notch, a slit or the like other than a hole or a groove. A hole is not limited to being a penetrating hole, but may also be a non-penetrating hole. A hole may be a via hole, through hole or the like, and the conductor formed in a via hole is referred to as a via conductor, and the conductor formed in a through hole is referred to a through-hole conductor. An imaging element being positioned in an opening portion includes cases where the entire imaging element is completely accommodated in the opening portion, as well as cases where only part of the imaging element is positioned in the opening portion.

Plating includes dry plating such as PVD (physical vapor deposition) and CVD (chemical vapor deposition) along with wet plating such as electrolytic plating.

When dimensions (such as thickness) of different shapes are compared, after the most appropriate values are compared among the values at a corresponding position of each shape, average values, maximum values and the like, while functions and effects obtained by such dimensions are considered, it is preferred to determine whether such values are the same or not. However, that is not the only option if values to be compared are described clearly.

### First Embodiment

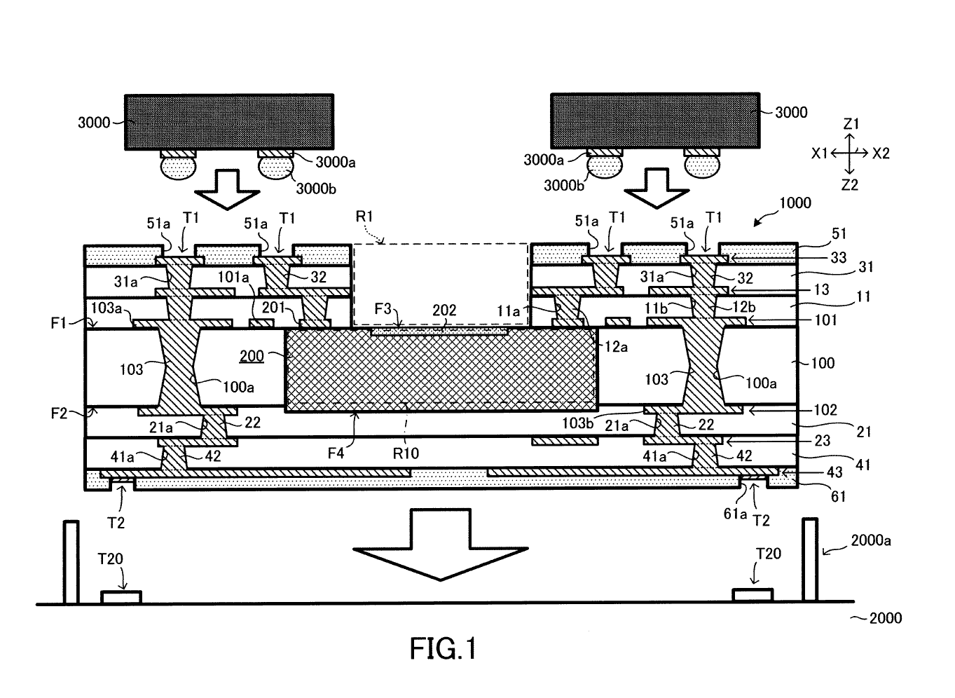

Wiring board 1000 of the present embodiment is a wiring board with a built-in imaging element. As shown in FIG. 1, wiring board 1000 has substrate 100 (core substrate), imaging element 200, insulation layers (11, 21, 31, 41) (interlayer insulation layers), conductive layers (101, 102, 13, 23, 33, 43), via conductors (12a, 12b, 22, 32, 42) and solder resists (51, 61).

Wiring board 1000 is a buildup multilayer printed wiring board, and substrate 100 is the core substrate of wiring board 1000. In the following, among the upper and lower surfaces (two main surfaces) of substrate 100, the surface on which insulation layer 11 (first insulation layer) is formed is referred to as first surface (F1), and the surface opposite first surface (F1) is referred to as second surface (F2). In the present embodiment, the number of first insulation layers (insulation layers (11, 31) and solder resist 51) laminated on first surface (F1) of substrate 100 and the number of second insulation layers (insulation layers (21, 41) and solder resist 61) laminated on second surface (F2) of substrate 100 are the same (three). Insulation layers are each separated by a conductive layer.

On the first-surface (F1) side of substrate 100, two insulation layers (11, 31) (each a first insulation layer) and two conductive layers (13, 33) are alternately laminated; and on the second-surface (F2) side of substrate 100, two insulation layers (21, 41) (each a second insulation layer) and two conductive layers (23, 43) are alternately laminated. Insulation layer 31 is formed on insulation layer 11, and insulation layer 41 is formed on insulation layer 21. Via conductors (12a, 12b) are formed in insulation layer 11, and via conductors (22, 32, 42) are formed respectively in insulation layers (21, 31, 41). Via conductors (12a, 12b, 22, 32, 42) electrically connect their respective upper and lower conductive layers through an interlayer insulation layer. In addition, through-hole conductor 103 is formed in substrate 100, and conductive layers (101, 102) on both surfaces of substrate 100 are electrically connected to each other via through-hole conductor 103. Via conductors (12b, 32) and through-hole conductor 103 are each a filled conductor, and they are stacked in a direction Z. Wiring board 1000 of the present embodiment is a rigid wiring board. However, wiring board 1000 may also be a flexible wiring board.

Opening portion (R10) in a rectangular sheet shape, for example, is formed in substrate 100. Opening portion (R10) is a hole that penetrates through substrate 100. Imaging element 200 is a sensor chip having an outline (such as a rectangular sheet) corresponding to the shape of opening portion (R10), for example. The thickness of imaging element 200 substantially corresponds to the depth of opening portion (R10) (a hole). Also, the thickness of substrate 100 including conductive layers (101, 102) on both surfaces substantially corresponds to the thickness of imaging element 200 including electrode 201. Imaging element 200 is positioned on a side of substrate 100 (either direction X or direction Y) by being placed in opening portion (R10). In the present embodiment, substantially the entire imaging element 200 is completely accommodated in opening portion (R10). However, the present embodiment is not limited to such, and only part of imaging element 200 may be positioned in opening portion (R10). Also, in the present embodiment, imaging element 200 is fitted in opening portion (R10) so that imaging element 200 is fixed to substrate 100. However, the present embodiment is not limited to such, and imaging element 200 and substrate 100 may be connected using an adhesive agent. In addition, resin that has flowed from insulation layers (11, 21) may be filled in the space between imaging element 200 and substrate 100.

Imaging element 200 is a chip of a CCD (charge coupled device) image sensor, for example. However, the type of imaging element 200 is not limited specifically to the above. For example, it may be a chip of a CMOS (complementary metal oxide semiconductor) image sensor. Imaging element 200 has electrode 201 and light receiver 202. Hereinafter, of the upper and lower surfaces (two main surfaces) of imaging element 200, the surface on which light receiver 202 is formed is referred to as third surface (F3) and the surface opposite third surface (F3) is referred to as fourth surface (F4). Imaging element 200 is positioned in opening portion (R10) in such a way that third surface (F3) faces in the same direction as first surface (F1) of substrate 100 In the present embodiment, third surface (F3) corresponds to the sensor surface, and fourth surface (F4) corresponds to the chip bottom. The shape of the main surfaces of imaging element 200 and the shape of light receiver 202 are both substantially rectangular. However, the shapes and the like of imaging element 200 and its light receiver 202 are not limited specifically to the above.

Conductive layer 33 is the outermost layer of one side (Z1 side) of wiring board 1000, and conductive layer 43 is the outermost layer of the other side (Z2 side) of wiring board 1000. Solder resist 51 (first insulation layer) and solder resist 61 (second insulation layer) are formed respectively on conductive layers (33, 43). However, since solder resists (51, 61) have opening portions (51a, 61a) respectively, solder resists (51, 61) are not formed on conductive layers (33, 43) in opening portions (51a, 61a).

A predetermined portion of conductive layer 33 (a portion corresponding to opening portion 51a) is exposed without being covered by solder resist 51 and becomes external connection terminal (T1) (pad) for mounting an electronic component. Electrode (3000a) of electronic component 3000 is electrically connected to external connection terminal (T1) (pad) of wiring board 1000 via solder (3000b) (solder bump), for example. Namely, electronic component 3000 (soldering, for example) is mounted on wiring board 1000 through external connection terminal (T1). To mitigate mismatching of thermal expansion coefficients, insulative underfill material may be filled between wiring board 1000 and electronic component 3000. As described, a predetermined portion of outermost conductive layer 33 works as external connection terminal (T1) for mounting an electronic component in the present embodiment.

In addition, external connection terminal (T2) (conductive pin) for connection with another wiring board is formed in the outermost layer (conductive layer 43) opposite external connection terminal (T1). More specifically, a predetermined portion of conductive layer 43 (portion corresponding to opening portion 61a) is exposed without being covered by solder resist 61 and becomes external connection terminal (T2) (pad) for connection with anther wiring board.

External connection terminal (T2) (pad) of wiring board 1000 is connected to, for example, pad (T20) of socket (2000a) in motherboard 2000. In doing so, wiring board 1000 and motherboard 2000 are electrically connected. Namely, wiring board 1000 is mounted on another wiring board such as motherboard 2000 through external connection terminal (T2). In the present embodiment, conductive layers (23, 43) on the second-surface (F2) side of substrate 100 have conductive patterns that fan out. As described, wiring board 1000 of the present embodiment has external connection terminal (T2) for connection with another wiring board on the outermost layer opposite external connection terminal (T1).

When motherboard 2000 is a circuit board for a cell phone, by arranging a lens block in light receiver 202 of imaging element 200, for example, wiring board 1000 is formed as a camera module of a cell phone.

Substrate 100 is made of resin, for example. In particular, substrate 100 is made by, for example, impregnating glass cloth as core material with epoxy resin (hereinafter referred to as glass epoxy). Namely, substrate 100 is made of resin containing core material in the present embodiment. Core material is a material having a smaller thermal expansion coefficient than a main material (epoxy resin in the present embodiment). The shape, thickness, material and the like of insulation layers are basically determined freely. For example, instead of epoxy resin, the following may also be used: polyester resin, bismaleimide triazine resin (BT resin), imide resin (polyimide), phenol resin, allyl polyphenylene ether resin (A-PPE resin) or the like. In addition, as for the core material, for example, glass fabric (such as glass cloth or glass non-woven fabric), aramid fabric (such as aramid non-woven fabric), or inorganic material such as silica filler is preferred.

Conductive layer 101 is formed on first surface (F1) of substrate 100, and conductive layer 102 is formed on second surface (F2) of substrate 100. Through hole (100a) is formed in substrate 100. By filling conductor (such as copper plating) in through hole (100a), through-hole conductor 103 is formed. The shape of through-hole conductor 103 is like that of an hourglass, for example. However, through-hole conductor 103 is not limited to such a shape and may be any other shape; for example, it may be substantially columnar. Through-hole conductor 103 connects conductive layer 101 and conductive layer 102 to each other, for example. Conductive layer 101 includes land (103a) of through-hole conductor 103 and other wiring (101a), and conductive layer 102 includes land (103b) of through-hole conductor 103.

In the present embodiment, insulation layers (21, 41) are made of resin containing core material, and insulation layers (11, 31) are made of resin without core material. As for the core material, for example, glass fabric (such as glass cloth or glass non-woven fabric), aramid fabric (such as aramid non-woven fabric), or inorganic material such as silica filler is preferred. In the present embodiment, insulation layers (21, 41) are each made of glass epoxy, and insulation layers (11, 31) are each made of epoxy resin, for example. Accordingly, the thermal expansion coefficient of insulation layers (21, 41) (each a second insulation layer) is lower than the thermal expansion coefficient of insulation layers (11, 31) (each a first insulation layer). Therefore, warping of wiring board 1000 tends to be reduced. However, the shape, thickness, material and the like of insulation layers (11, 21, 31, 41) are not limited to the above, and they are basically determined freely. For example, instead of epoxy resin, the following may also be used: polyester resin, bismaleimide triazine resin (BT resin), imide resin (polyimide), phenol resin, allyl polyphenylene ether resin (A-PPE resin) or the like. Each insulation layer may be formed with multiple layers of different materials.

The method for adjusting thermal expansion coefficients is not limited to whether or not core material is contained. For example, even if both the first insulation layers (such as insulation layer 11) on the first-surface (F1) side of substrate 100 and the second insulation layers (such as insulation layer 21) on the second-surface (F2) side of substrate 100 contain core material, by modifying the amount of core material (such as filler), more specifically, by making the amount of core material in the second insulation layers greater than the amount of core material in the first insulation layers, the thermal expansion coefficient of the second insulation layers is set lower than the thermal expansion coefficient of the first insulation layers. Alternatively, thermal expansion coefficients may be adjusted by modifying the materials respectively forming the first insulation layers and the second insulation layers (the type of resin, for example).

Conductive layers (101, 102, 13, 23, 33, 43) and via conductors (12a, 12b, 22, 32, 42) are each made of copper, for example (in particular, any one of copper foil, electroless copper plating, electrolytic copper plating, a combination of those, or the like). However, the material of conductive layers and via conductors is not limited to the above and may be selected freely. Each conductive layer and each via conductor may be formed with multiple layers of different materials.

Solder resists (51, 61) are made of, for example, resins such as photosensitive resin using an acrylic-epoxy type resin, thermosetting resin mainly containing epoxy resin, ultraviolet setting resin, or the like. However, the material of solder resists (51, 61) is not limited specifically to the above. Solder resists (51, 61) may also be formed with multiple layers of different materials.

Insulation layer 11 is formed on first surface (F1) of substrate 100. Conductive layer 13 is formed on insulation layer 11. Insulation layer 31 is formed on conductive layer 13. Conductive layer 33 is formed on insulation layer 31. Conductive layer 33 becomes an outermost layer.

Insulation layer 11 is formed not only on first surface (F1) of substrate 100 but also on third surface (F3) of imaging element 200 in such a way to expose light receiver 202 of imaging element 200. In particular, in insulation layer 11, insulation layer 31 and solder resist 51, opening portion (R1) is formed for exposing light receiver 202 of imaging element 200. Opening portion (R1) is a hole that penetrates through insulation layer 11, insulation layer 31 and solder resist 51 and reaches light receiver 202 of imaging element 200. Light receiver 202 is exposed through opening portion (R1).

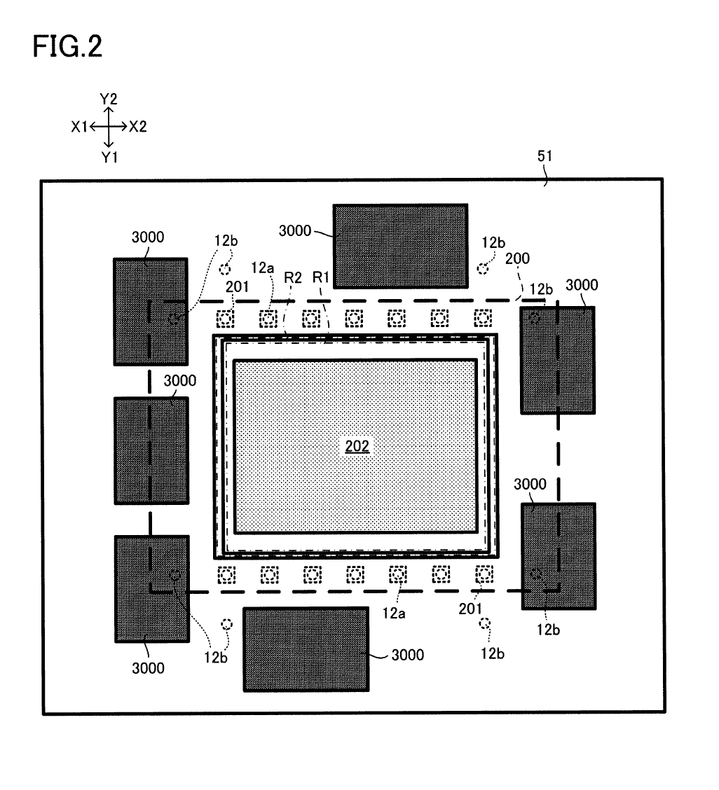

As shown in FIGS. 1 and 2, in the present embodiment, light receiver 202 is positioned in the central portion of imaging element 200 and electrodes 201 are positioned in the peripheral portions (two facing sides, for example) of imaging element 200. Insulation layer 11 formed on imaging element 200 covers the entire peripheral portion (four sides) of imaging element 200 including electrodes 201. An edge of insulation layer 11 (a peripheral portion of opening portion R1) is positioned on a peripheral portion of imaging element 200. The side surface of insulation layer 11 and the side surface of insulation layer 31 which face opening portion (R1) are substantially on the same plane. In the present embodiment, that plane is substantially perpendicular to third surface (F3) (sensor surface) of imaging element 200. The shape of opening portion (R1) is substantially rectangular, for example. Conductive layer 13 includes a conductive pattern that extends to the vicinity of the side surface of insulation layer 31 facing opening portion (R1). The side surface of the conductive pattern is positioned in substantially the same location as the side surface of insulation layer 31 facing opening portion (R1).

The horizontal cross section (X-Y plane) of opening portion (R1) is shaped to be substantially rectangular, for example. The difference between the width of opening portion (R1) and the width of opening portion (R2) is preferred to be in such a range that a step (step portion S1) is secured while wiring regions are not sacrificed. In particular, it is preferred to be in the range of approximately 10 μm or greater to approximately 100 μm or less. Opening portion (R1) of the present embodiment has a shape corresponding to light receiver 202 (a similar shape with substantially the same size, for example), and mostly exposes only light receiver 202.

Holes (11a, 11b) (via holes) are formed in insulation layer 11. By filling conductor (for example, copper plating) in holes (11a, 11b) respectively, the conductors in holes (11a, 11b) become via conductors (12a, 12b) respectively (filled conductors). Hole (11a) exposes electrode 201 of imaging element 200, and via conductor (12a) in hole (11a) is connected to electrode 201. Electrode 201 of imaging element 200 and conductive layer 13 on insulation layer 11 are electrically connected to each other through via conductor (12a). In addition, conductive layer 101 on substrate 100 (core substrate) and conductive layer 13 on insulation layer 11 are electrically connected to each other through via conductor (12b).

Hole (31a) (via hole) is formed in insulation layer 31. By filling conductor (for example, copper plating) in hole (31a), the conductor in hole (31a) becomes via conductor 32 (filled conductor). Hole (31a) exposes conductive layer 13, and via conductor 32 in hole (31a) is connected to conductive layer 13. Conductive layer 13 on insulation layer 11 and conductive layer 33 on insulation layer 31 are electrically connected to each other through via conductor 32.

As described above, hole (11a) reaching electrode 201 of imaging element 200 is formed in insulation layer 11, and hole (31a) reaching conductive layer 13 is formed in insulation layer 31 in the present embodiment. Electrode 201 of imaging element 200 and external connection terminal (T1) are electrically connected to each other through the conductor in hole (11a) (via conductor 12a), conductive layer 13 and the conductor in hole (31a) (via conductor 32).

Meanwhile, insulation layer 21 is formed on second surface (F2) of substrate 100. Conductive layer 23 is formed on insulation layer 21. Insulation layer 41 is formed on conductive layer 23. Conductive layer 43 is formed on insulation layer 41. Conductive layer 43 becomes the outermost layer.

Wiring board 1000 has insulation layer 21 on second surface (F2) of substrate 100. Insulation layer 21 blocks the opening of one side (opening on the Z2 side) of opening portion (R10) (hole). Accordingly, opening portion (R10) is formed as a hole with a bottom (recessed portion). Insulation layer 21 covers fourth surface (F4) of imaging element 200.

Via conductors (12a, 12b, 22, 32, 42) are each made of copper plating, for example. The shape of via conductors (12a, 12b, 22, 32, 42) is, for example, a tapered column (truncated cone) that tapers with a diameter increasing from the side of substrate 100 (core substrate) toward a further upper layer. The shape of horizontal cross sections of via conductors (X-Y plane) is substantially a complete circle, for example. However, the shape of via conductors is not limited to such, and may be any other shape.

Via conductors (12a, 12b, 22, 32, 42) and through-hole conductor 103 positioned near imaging element 200 are each preferred to be a filled conductor. In doing so, strength near imaging element 200 is enhanced. Especially, since via conductors (12b, 32) and through-hole conductor 103 are stacked in the present embodiment, even greater strength is obtained. In addition, those filled conductors are preferred to be positioned in such a manner that would mitigate stress exerted on imaging element 200. Specifically, as shown in FIG. 2, for example, it is preferred that via conductor (12a) be positioned around light receiver 202 and the stack structure (via conductors (12b) and the like) be positioned on the outer side of via conductor (12b) (four corners of imaging element 200, for example).

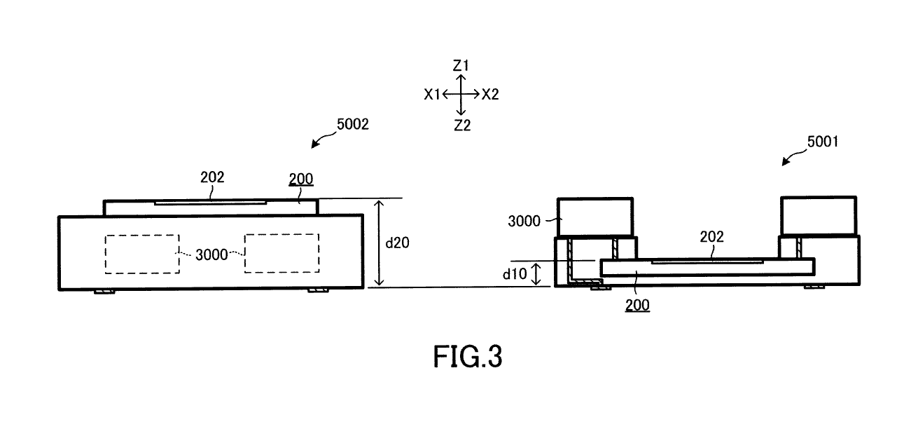

The height of wiring board 1000 (wiring board with a built-in imaging element) of the present embodiment is easily set lower because of the above structure. In the following, the reasons are described by referring to FIG. 3. FIG. 3 is a view to compare the dimensions (in particular, the height from the bottom surface to light receiver 202) in imaging device 5001 formed using wiring board 1000 of the present embodiment and imaging device 5002 relating to a comparative example. In FIG. 3, for the ease of description, the same numerical reference is applied to the elements corresponding to each other in imaging device 5001 and imaging device 5002.

Imaging element 200 is mounted on a surface of imaging device 5002. Height (d20) from the bottom surface to light receiver 202 in imaging device 5002 is approximately 0.6˜approximately 0.8 mm, for example. By contrast, since imaging element 200 is built into imaging device 5001, it is easier to reduce height (d10) from the bottom surface to light receiver 202 in imaging device 5001. Specifically, height (d10) is reduced to approximately 0.3 mm. As described, wiring board 1000 of the present embodiment has a structure where the sensor surface is easily set lower.

In wiring board 1000 of the present embodiment, since third surface (F3) (sensor surface) of imaging element 200 is set at a lower position, the height of the entire module is reduced. As a result, it is easier to respond to a larger lens block and a higher number of pixels of imaging element 200 (image sensor). In addition, effects such as light receiver 202 of imaging element 200 becoming resistant to damage are expected.

In wiring board 1000 of the present embodiment, when identical ordinal numbers counted from substrate 100 are compared, at all the ordinal numbers (tiers), the thermal expansion coefficient of the interlayer insulation layers (insulation layers 21 and 41) laminated on second surface (F2) of substrate 100 is lower than the thermal expansion coefficient of interlayer insulation layers (insulation layers 11, 31) laminated on first surface (F1) of substrate 100. Namely, the thermal expansion coefficient of the n-th (n: any natural number) interlayer insulation layer laminated on second surface (F2) of substrate 100 is set lower than the thermal expansion coefficient of the n-th interlayer insulation layer laminated on the first surface (F1) of substrate 100. Specifically, at the first layers counted from substrate 100, the thermal expansion coefficient of insulation layer 21 (second insulation layer) is lower than the thermal expansion coefficient of insulation layer 11 (first insulation layer); and at the second layers from substrate 100, the thermal expansion coefficient of insulation layer 41 (second insulation layer) is lower than the thermal expansion coefficient of insulation layer 31 (first insulation layer). Accordingly, an imbalance in thermal expansion/thermal contraction caused by opening portion (R1) existing only on one side is offset or mitigated. Accordingly, warping in wiring board 1000 (especially near light receiver 202) tends to be reduced during heat cycles or the like.

Furthermore, if the thermal expansion coefficient of solder resist 61 (second insulation layer) is set lower than the thermal expansion coefficient of solder resist 51 (first insulation layer), the effect on warping reduction is further enhanced.

Since insulation layer 11 is formed not only on substrate 100 but also on imaging element 200 (a portion where no light receiver is formed), it is easier to secure a region for mounting electronic component 3000 on the surface. Moreover, since opening portion (R1) mostly exposes light receiver 202 only, an even greater region is ensured on the surface.

In wiring board 1000 of the present embodiment, hole (11a) reaching electrode 201 of imaging element 200 is formed in insulation layer 11 (a portion where no opening is formed), and electrode 201 of imaging element 200 and conductive layer 13 on insulation layer 11 are electrically connected through via conductor (12a) in hole (11a). Moreover, wiring board 1000 of the present embodiment has two buildup layers (insulation layer 11 and conductive layer 13, insulation layer 31 and conductive layer 33). Accordingly, it is easier to respectively secure a wiring region for imaging element 200 in the inner layer (conductive layer 13) of wiring board 1000, and a mounting region for electronic component 3000 in the outer layer (conductive layer 33) of wiring board 1000.

In the present embodiment, conductive layer 13 includes a conductive pattern that extends to the vicinity of the side surface of insulation layer 31 facing opening portion (R1). Since conductive layer 13 made of copper (metal) is harder than insulation layer 31 made of resin, force tends to be dispersed by the conductive pattern.

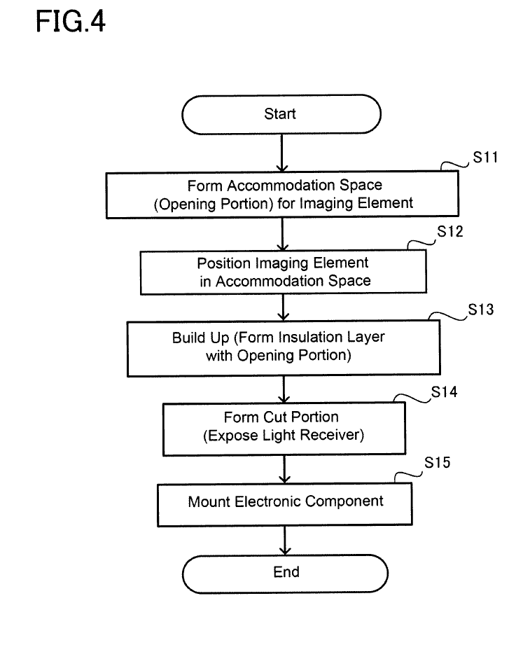

In the following, a method for manufacturing wiring board 1000 is described with reference to FIG. 4 or the like. FIG. 4 is a flowchart outlining the contents and order of the method for manufacturing wiring board 1000 according to the present embodiment.

In step (S11), as shown in FIG. 5, wiring board 1001 (starting material) is prepared, and using a laser or a drill, for example, opening portion (R10) (accommodation space for imaging element 200) is formed in wiring board 1001 (in particular substrate 100). Opening portion (R10) is a hole that penetrates through substrate 100.

Wiring board 1001 is a double-sided copper-clad laminate, for example. In the present embodiment, wiring board 1001 is formed with substrate 100, conductive layer 101 formed on first surface (F1) of substrate 100, conductive layer 102 formed on second surface (F2) of substrate 100, and through-hole conductor 103. Conductive layers (101, 102) have a double-layer structure of copper foil (lower layer) and electrolytic copper plating (upper layer), for example. Hourglass-shaped through hole (100a) is formed by irradiating a laser from both sides of substrate 100, for example. By performing electrolytic copper plating, for example, where copper foil is formed on substrate 100 and through hole (100a) is formed in substrate 100, conductive layers (101, 102) and through-hole conductor 103 are formed.

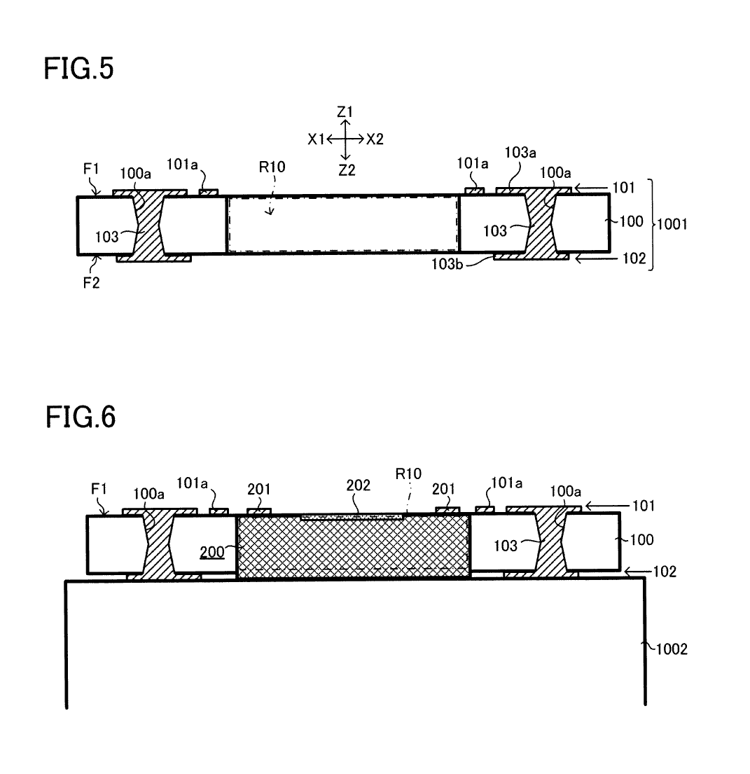

As shown in FIG. 6, wiring board 1001 having opening portion (R10) is placed on carrier 1002 (base stand). Carrier 1002 is attached to the second-surface (F2) side of substrate 100.

In step (S12) in FIG. 4, imaging element 200 is positioned in opening portion (R10) of wiring board 1001 as shown in FIG. 6. During that time, imaging element 200 may be fixed onto carrier 1002, or it may be fixed by fitting it in opening portion (R10) and using friction force with substrate 100, or it may be fixed to substrate 100 using an adhesive agent or the like.

Carrier 1002 is removed from the wiring board. The wiring board is cleansed if required. Carrier 1002 may be removed prior to placing mask 1003.

In step (S13) in FIG. 4, building up is conducted on each main surface (first surface (F1), second surface (F2)) of substrate 100 (core substrate).

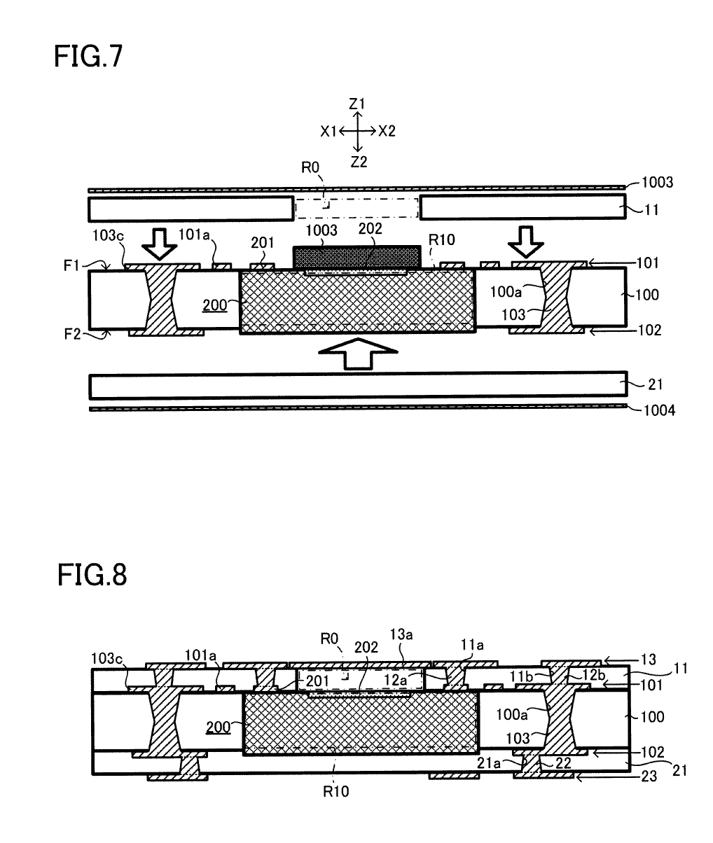

Specifically, insulation layer 11 having opening portion (R0) is formed on first surface (F1) of substrate 100, and insulation layer 21 is formed on second surface (F2) of substrate 100 as shown in FIG. 7. Conductive layer 101 and electrode 201 are covered by insulation layer 11, and conductive layer 102 is covered by insulation layer 21. Also, copper foils (1003, 1004) are formed respectively on insulation layers (11, 21). Insulation layer 11 is made of epoxy resin, for example, and insulation layer 21 is made of glass epoxy, for example.

Substrate 100 and insulation layers (11, 21) are adhered through pressing or lamination, for example. When they are adhered through pressing, for example, while insulation layers (11, 21) are prepreg, they are adhered to substrate 100 through pressing, and cured by adding heat. During that time, resin (insulative body 104) flowed from insulation layers (11, 21) is filled in through hole (100a). However, the present embodiment is not limited to such. For example, prior to pressing or lamination, insulative body 104 may be separately prepared and be filled in through hole (100a). Also, prior to pressing, copper foil may be placed on insulation layers (11, 21).

As shown in FIG. 8, holes (11a, 11b) (via holes) are formed in insulation layer 11 using a laser, for example, and hole (21a) (via hole) is formed in insulation layer 21 using a laser, for example. Desmearing is conducted if required.

As shown in FIG. 8, electroless copper-plated film is formed by a chemical plating method, for example, and electrolytic copper-plated film is further formed on its top by a pattern plating method, for example. Specifically, after electroless plated film is formed by immersing the wiring board having via holes in a plating solution, electrolytic plated film is formed by using plating resist having opening portions corresponding to conductive layer 13 and conductive pattern (13a) or to the conductive pattern of conductive layer 23. By removing unnecessary electroless plating, conductive layer 13 and conductive pattern (13a) are formed on insulation layer 11, and conductive layer 23 is formed on insulation layer 21, while via conductors (12a, 12b, 22) are formed respectively in holes (11a, 11b, 21a). The shape of conductive pattern (13a) is substantially a plane sheet, for example. In the present embodiment, conductive pattern (13a) has a size a little larger than light receiver 202 of imaging element 200, and is positioned directly on the entire light receiver 202 (in a direction Z) as shown in FIG. 9. Here, prior to electroless plating, surfaces of insulation layers (11, 21) may be roughened, a catalyst may be adsorbed, or the like.

Buildup is further continued.

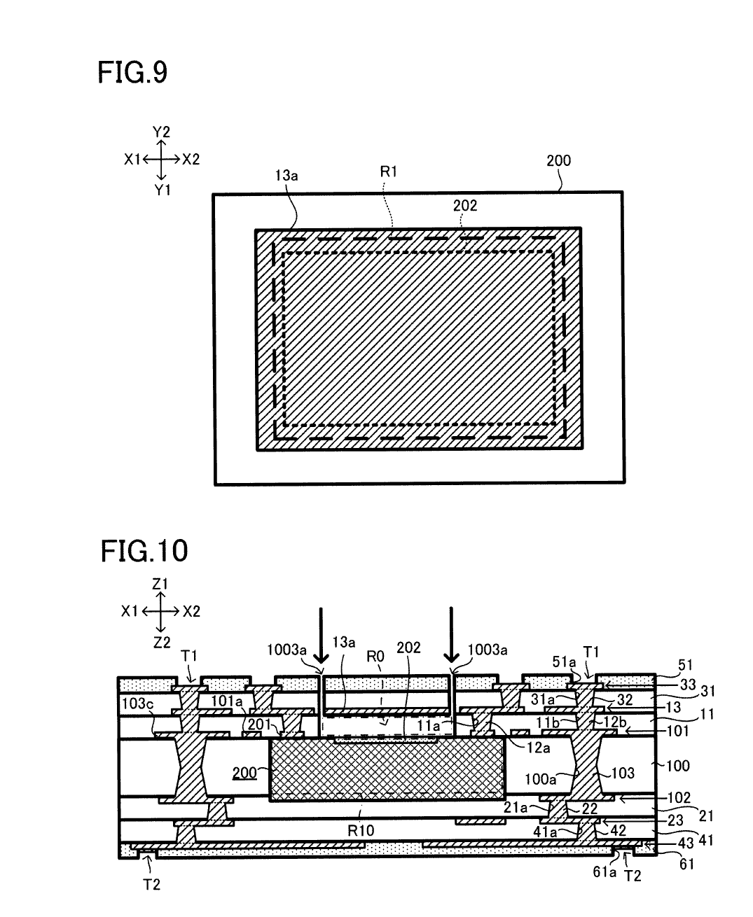

Specifically, insulation layer 31 and copper foil (copper foil with resin, for example) are formed on insulation layer 11, and insulation layer 41 and copper foil (copper foil with resin, for example) are formed on insulation layer 21 as shown in FIG. 10. Insulation layer 31 is made of epoxy resin, for example, and insulation layer 41 is made of glass epoxy, for example.

By a method the same as the above method for forming lower layers (FIGS. 7, 8), for example, holes (31a, 41a), via conductors (32, 42) and conductive layers (33, 43) are formed as shown in FIG. 10. Here, conductive layer 33 may include a plane conductive pattern to be positioned directly on entire light receiver 202 (in a direction Z).

Since conductive layers (33, 43) become outermost layers and predetermined portions of conductive layers (33, 43) become pads that are not covered with solder resists (51, 61), Ni/Au film (corrosion resistant metal film) may be formed on conductive layers (33, 43) (pads) by electrolytic Ni plating, sputtering or the like, for example, or an OSP treatment may be conducted.

Solder resist 51 having opening portion (51a) and solder resist 61 having opening portion (61a) are formed respectively on insulation layers (31, 41) as shown in FIG. 10. Conductive layers (33, 43) are covered with solder resists (51, 61) respectively except for predetermined portions corresponding to opening portions (51a, 61a). A predetermined portion of conductive layer 33 (portion corresponding to opening portion (51a)) becomes external connection terminal (T1) (pad) for mounting an electronic component. Also, a predetermined portion of conductive layer 43 (portion corresponding to opening portion (61a)) becomes external connection terminal (T2) (pad) for connection with another wiring board. Solder resists (51, 61) are formed, for example, by screen printing, spray coating, roll coating, lamination or the like.

External connection terminal (T2) (conductive pin) is connected to conductive layer 43 (pad) exposed through opening portion (61a) of solder resist 61 using a conductive adhesive agent (such as solder ball or solder paste), for example. External connection terminal (T2) (conductive pin) does not have to be connected at this time, but may be connected later. For example, external connection terminal (T2) may be connected after step (S16) in FIG. 4.

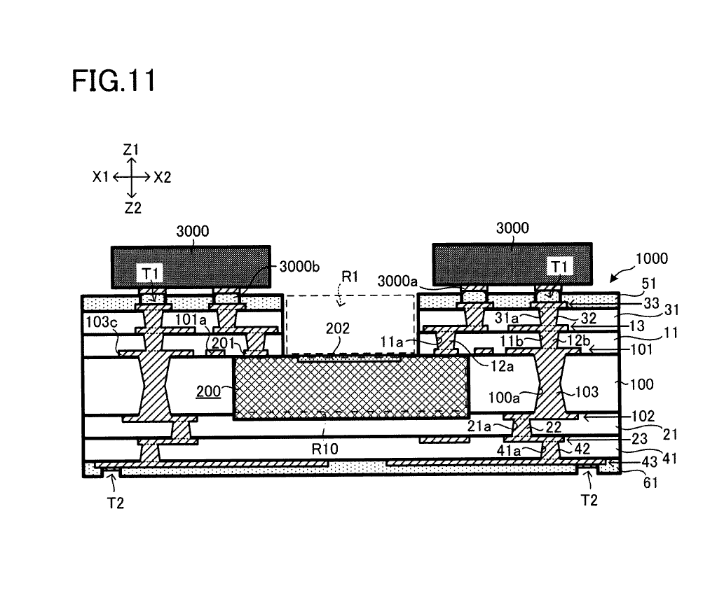

In step (S14) in FIG. 4, by forming an opening portion to be connected to opening portion (R0) in insulation layer 31, light receiver 202 of imaging element 200 is exposed. Specifically, as shown in FIG. 10, for example, recessed portion (1003a) penetrating through insulation layer 31 and reaching insulation layer 11 is formed. Recessed portion (1003a) is formed using a laser, for example. However, the method for forming recessed portion (1003a) is not limited to using a laser, and dry etching or the like may also be used, for example. Recessed portion (1003a) is a groove, for example, which is formed continuously on the entire circumference of opening portion (R0). However, as long as opening portion (R1) (FIG. 11) is formed, the manner for forming recessed portion (1003a) on the circumference of opening portion (R0) (shape, dimensions and the like) is not limited specifically. For example, recessed portion (1003a) is not limited to being a groove formed to be continuous, and it may be formed as a dotted line which surrounds opening portion (R0).

Recessed portion (1003a) is formed by a laser, for example. By forming recessed portion (1003a), insulation layer 11, conductive pattern (13a), insulation layer 31 and solder resist 51 which are on opening portion (R0) are separated from their surroundings. The separated section on opening portion (R0) is removed manually or by adding external force using other methods, for example. Accordingly, light receiver 202 of imaging element 200 is exposed.

Through the above steps, wiring board 1000 of the present embodiment (wiring board with a built-in imaging element) is manufactured. The manufacturing method of the present embodiment is suitable for manufacturing wiring board 1000. According to such a manufacturing method, an excellent wiring board 1000 is obtained at low cost.

In step (S15) in FIG. 4, electronic component 3000 is mounted on wiring board 1000. Specifically, electronic component 3000 is mounted on external connection terminal (T1) through soldering, for example, as shown in FIG. 11. Electrode (3000a) of electronic component 3000 is electrically connected to external connection terminal (T1) (pad) of wiring board 1000 via solder (3000b) (solder bump), for example.

As shown in FIG. 1, wiring board 1000 is mounted on motherboard 2000, and a lens block is arranged in light receiver 202 of imaging element 200. Accordingly, an imaging device is completed.

### Second Embodiment

The second embodiment of the present invention is described focusing on differences with the above first embodiment. Here, the same numerical reference is applied to the corresponding identical element shown in above FIG. 1 and others, and for the ease of description, when a portion is already described, namely when its description would be redundant, such a description is omitted or simplified.

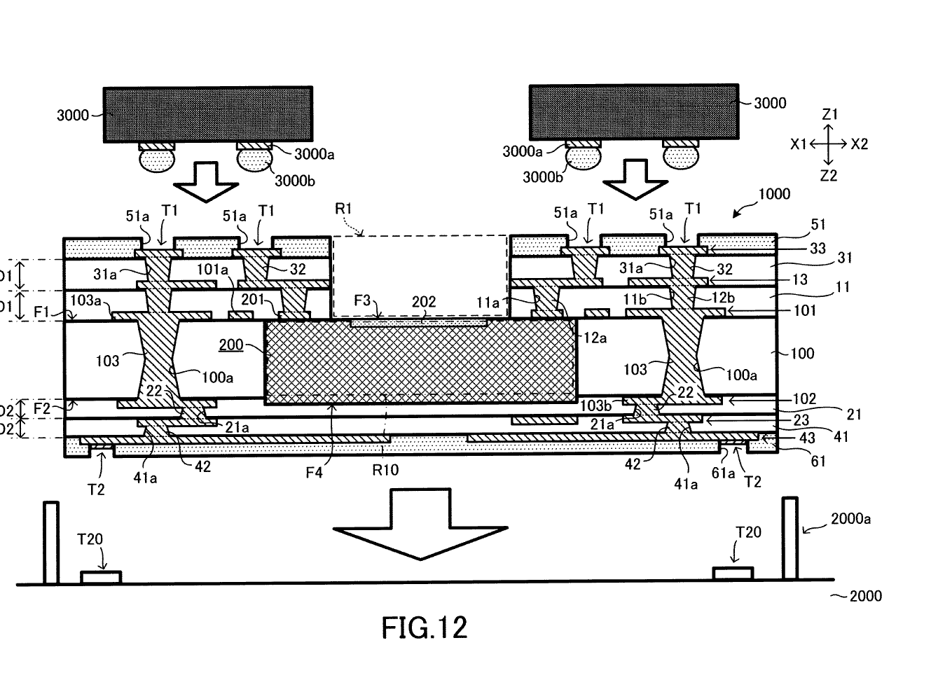

As shown in FIG. 12, wiring board 1000 of the present embodiment has substrate 100 in which opening portion (R10) is formed, imaging element 200 having light receiver 202 on the third-surface (F3) side and positioned in opening portion (R10) with third surface (F3) facing in the same direction as first surface (F1) of substrate 100, insulation layer 11 (first insulation layer) formed on first surface (F1) of substrate 100 in such a way to expose light receiver 202 of imaging element 200, and insulation layer 21 (second insulation layer) formed on second surface (F2) of substrate 100 and on fourth surface (F4) of imaging element 200. In the present embodiment, insulation layer 21 covers substantially the entire fourth surface (F4) of imaging element 200. In wiring board 1000 of the present embodiment, all interlayer insulation layers (insulation layers 11, 31) laminated on first surface (F1) of substrate 100 have thickness (D1), the same as each other, and all interlayer insulation layers (insulation layers 21, 41) laminated on second surface (F2) of substrate 100 have thickness (D2), the same as each other. When identical ordinal numbers counted from substrate 100 are compared, thickness (D2) of interlayer insulation layers (insulation layers 21 and 41) laminated on second surface (F2) of substrate 100 is less than thickness (D1) of interlayer insulation layers (insulation layers 11 and 31) laminated on first surface (F1) of substrate 100. Namely, the thickness of the n-th (n: any natural number) interlayer insulation layer laminated on second surface (F2) of substrate 100 is less than the thickness of the n-th interlayer insulation layer laminated on first surface (F1) of substrate 100. In particular, regarding the first layers counted from substrate 100, the thickness of insulation layer 21 (second insulation layer) is less than the thickness of insulation layer 11 (first insulation layer); and regarding the second layers counted from substrate 100, the thickness of insulation layer 41 (second insulation layer) is less than the thickness of insulation layer 31 (first insulation layer). Accordingly, an imbalance in thermal expansion/thermal contraction caused by opening portion (R1) existing only on one side is offset or mitigated. Therefore, warping in wiring board 1000 (especially near light receiver 202) tends to be reduced.

Furthermore, if the thickness of solder resist 61 (second insulation layer) is less than the thickness of solder resist 51 (first insulation layer), the effect on warping reduction is further enhanced.

Interlayer insulation layers (insulation layers 11, 31) laminated on first surface (F1) of substrate 100 or interlayer insulation layers (insulation layers 21, 41) laminated on second surface (F2) of substrate 100 may have a different thickness from each other.

Wiring board 1000 according to the present embodiment is manufactured, for example, by a manufacturing method substantially the same as the manufacturing method described in the first embodiment (FIG. 4).

In addition, regarding the same structure as in the first embodiment, substantially the same effects as in the above-described first embodiment are achieved.

### Third Embodiment

The third embodiment of the present invention is described focusing on differences with the above first embodiment. Here, the same numerical reference is applied to the corresponding identical element as shown in above FIG. 1 and others, and for the ease of description, when a portion is already described, namely when its description would be redundant, such a description is omitted or simplified.

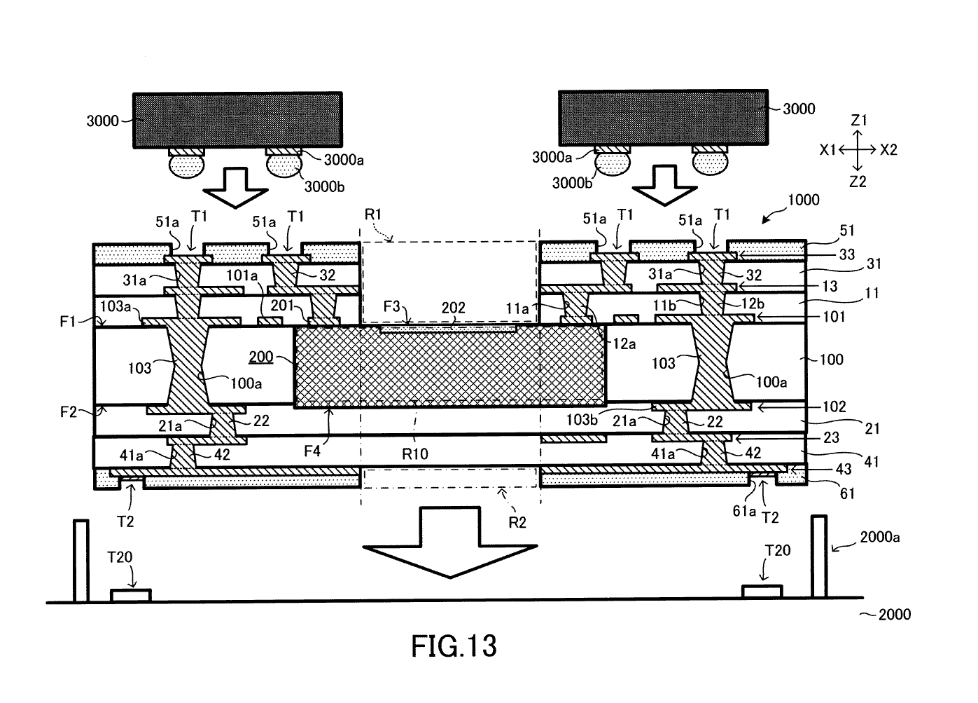

As shown in FIG. 13, wiring board 1000 of the present embodiment has substrate 100 in which opening portion (R10) is formed; imaging element 200 having light receiver 202 on the third-surface (F3) side, and positioned in opening portion (R10) in such a way that third surface (F3) faces in the same direction as first surface (F1); insulation layer 11 formed on first surface (F1) of substrate 100 in such a way to expose light receiver 202 of imaging element 200; and insulation layer 21 formed on second surface (F2) of substrate 100 and on fourth surface (F4) of imaging element 200. In insulation layer 11, insulation layer 31 and solder resist 51, opening portion (R1) is formed as a hole that penetrates through those layers and reaches light receiver 202 of imaging element 200.

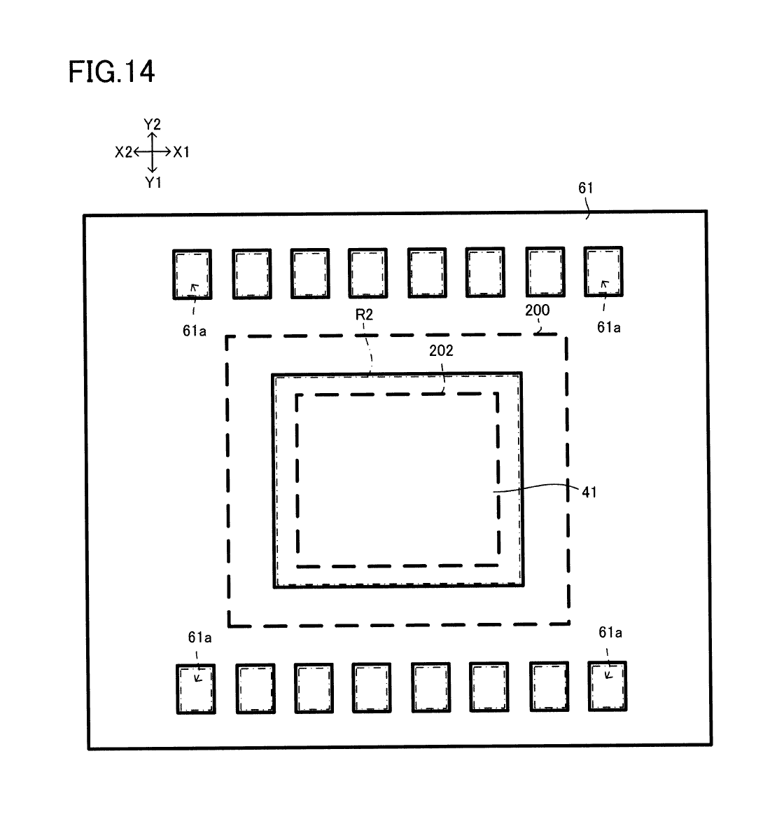

In the present embodiment, a portion on the surface (main surface) of the second-surface (F2) side corresponding to opening portion (R1) (hole) is made thinner than its surroundings. Specifically, wiring board 1000 of the present embodiment has solder resist 61 which is formed on the second-surface (F2) side of substrate 100 and on the fourth-surface (F4) side of imaging element 200. The portion corresponding to opening portion (R1) (hole) is completely removed from solder resist 61 to form opening portion (R2). When seen on the X-Y plane, opening portion (R2) overlaps opening portion (R1). Insulation layer 41 is exposed through opening portion (R2). As shown in FIGS. 13 and 14, the shape of opening portion (R2) is substantially rectangular, for example.

Opening portion (R1) and opening portion (R2) have overlapping portions in the present embodiment. When seen on the X-Y plane, opening portion (R2) is preferred to have substantially the same size and shape as opening portion (R1) and to be positioned at substantially the same location as opening portion (R1). The greater the symmetry of the upper and lower surfaces in imaging element 200, the less likely it is that warping occurs in wiring board 1000 (especially in light receiver 202).

In wiring board 1000 of the present embodiment, since a portion on the surface of the second-surface (F2) side (the side opposite opening portion R1) corresponding to opening portion (R1) is made thinner than its surroundings, the symmetry of the upper and lower surfaces of imaging element 200 is enhanced. Thus, an imbalance in thermal expansion/thermal contraction caused by opening portion (R1) existing only on one side is offset or mitigated. Accordingly, warping in wiring board 1000 (especially near light receiver 202) tends to be reduced.

In wiring board 1000 of the present embodiment, a predetermined portion positioned on the second-surface (F2) side of wiring board 1000 is removed from solder resist 61. According to such a structure, it is easier to form opening portion (R2) in a location corresponding to opening portion (R1) (hole). In addition, by screen printing, etching or the like, it is easier to obtain solder resist 61 having a required pattern. Thus, opening portion (R2) having any required shape is easier to obtain.

Wiring board 1000 of the present embodiment is manufactured by a method substantially the same as that described in the first embodiment (FIG. 4), for example. When forming opening portion (R2), it is an option to form solder resist on portions excluding opening portion (R2); or it is also an option to form solder resist on the entire surface and form opening portion (R2) by removing part of the solder resist through etching or the like.

Other than the above, with regard to a structure the same as that of the first embodiment, substantially the same effects as those in the above-described first embodiment are achieved.

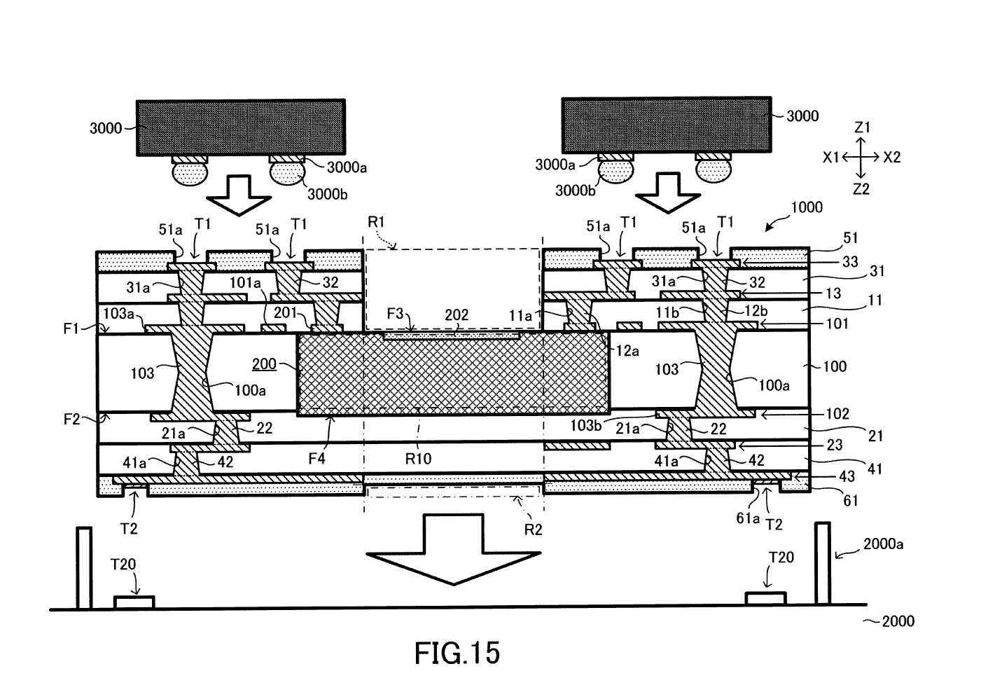

Without removing completely a portion corresponding to opening portion (R1) (hole) from solder resist 61, opening portion (R2) may be formed by making the portion thinner than its surroundings as shown in FIG. 15, for example. In such a case, the above effect on suppressing warping is achieved as well.

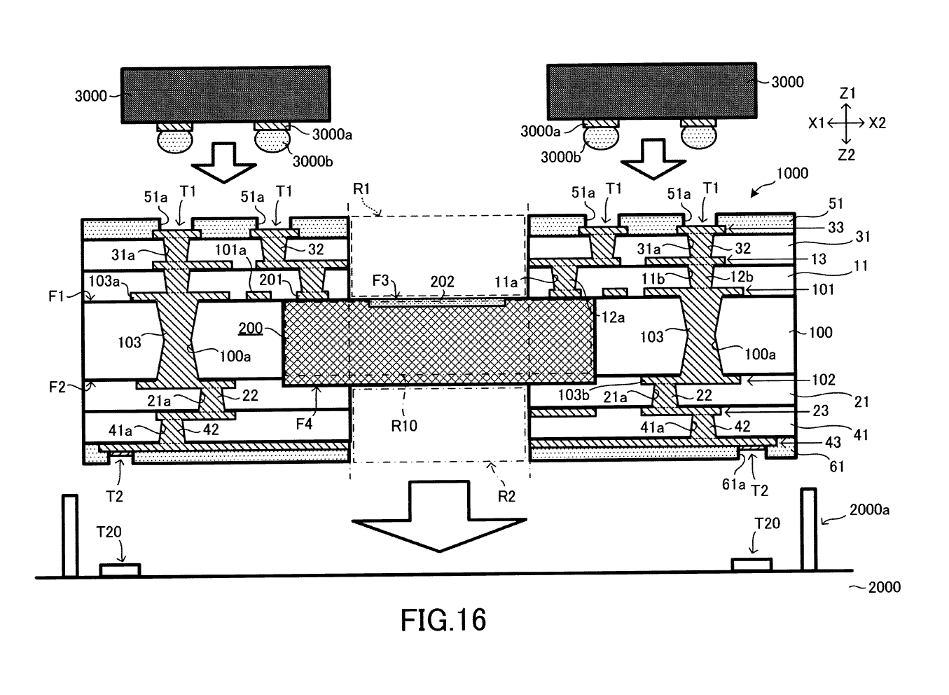

In addition, as shown in FIG. 16, along with a portion of solder resist 61 corresponding to opening portion (R1) (hole), portions of insulation layers (21, 41) corresponding to opening portion (R1) (hole) may also be removed to expose fourth surface (F4) of imaging element 200. In such a case, the above effect on suppressing warping is achieved as well.

### Fourth Embodiment

The fourth embodiment of the present invention is described focusing on differences with the above first embodiment. Here, the same numerical reference is applied to the corresponding identical element as shown in above FIG. 1 and others, and when a portion is already described, namely when its description would be redundant, such a description is omitted or simplified for the ease of description.

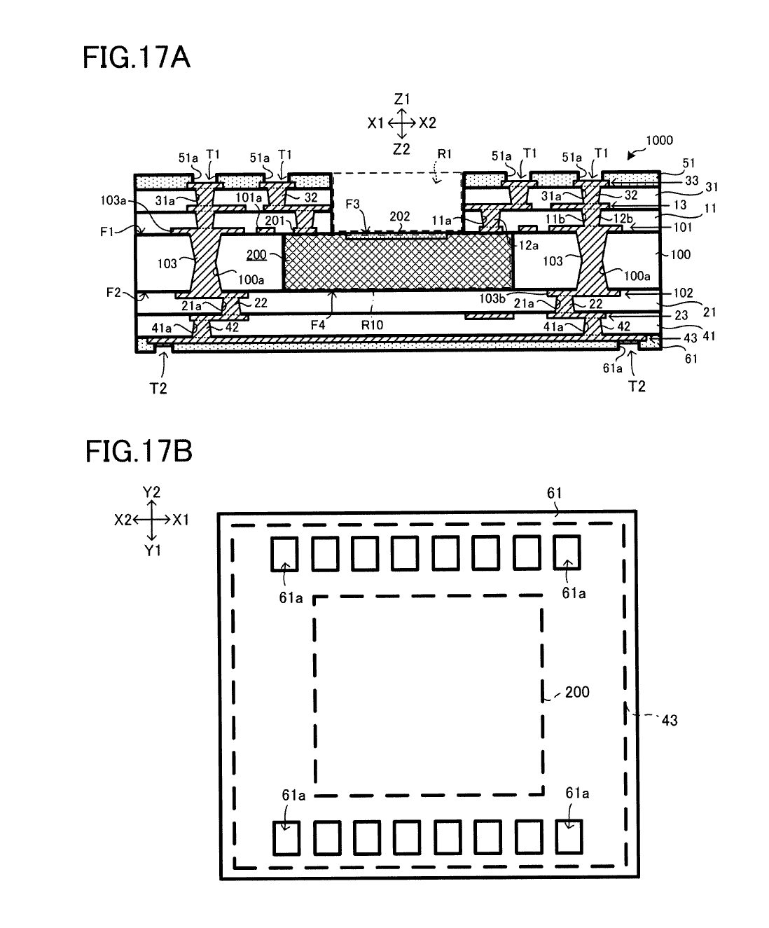

As shown in FIG. 17A, wiring board 1000 of the present embodiment has substrate 100 in which opening portion (R10) is formed; imaging element 200 having light receiver 202 on the third-surface (F3) side and positioned in opening portion (R10) in such a way that third surface (F3) faces in the same direction as first surface (F1) of substrate 100; insulation layer 11 formed on first surface (F1) of substrate 100 in such a way to expose light receiver 202 of imaging element 200; and insulation layer 21 formed on second surface (F2) of substrate 100 and on fourth surface (F4) of imaging element 200. In insulation layer 11, insulation layer 31 and solder resist 51, opening portion (R1) is formed as a hole that penetrates through those layers and reaches light receiver 202 of imaging element 200.

Wiring board 1000 of the present embodiment has a plane conductor (conductive layer 43) in a region on the fourth-surface (F4) side of imaging element 200 corresponding to opening portion (R1) (hole). When seen on the X-Y plane, the plane conductor in the present embodiment has a shape greater than opening portion (R1) and similar to the shape of opening portion (R1) as shown in FIG. 17B. The plane conductor and opening portion (R1) have overlapping portions.

In wiring board 1000 of the present embodiment, a plane conductor (conductive layer 43) is formed in a region on the fourth-surface (F4) side of imaging element 200 (the side opposite opening portion (R1)) corresponding to opening portion (R1). When the above structure is employed, since conductive layer 43 made of copper (metal) is harder than insulation layers (21, 41) made of resin, it is easier to suppress force caused by forming opening portion (R1). As a result, warping in wiring board 1000 (especially near light receiver 202) tends to be reduced.

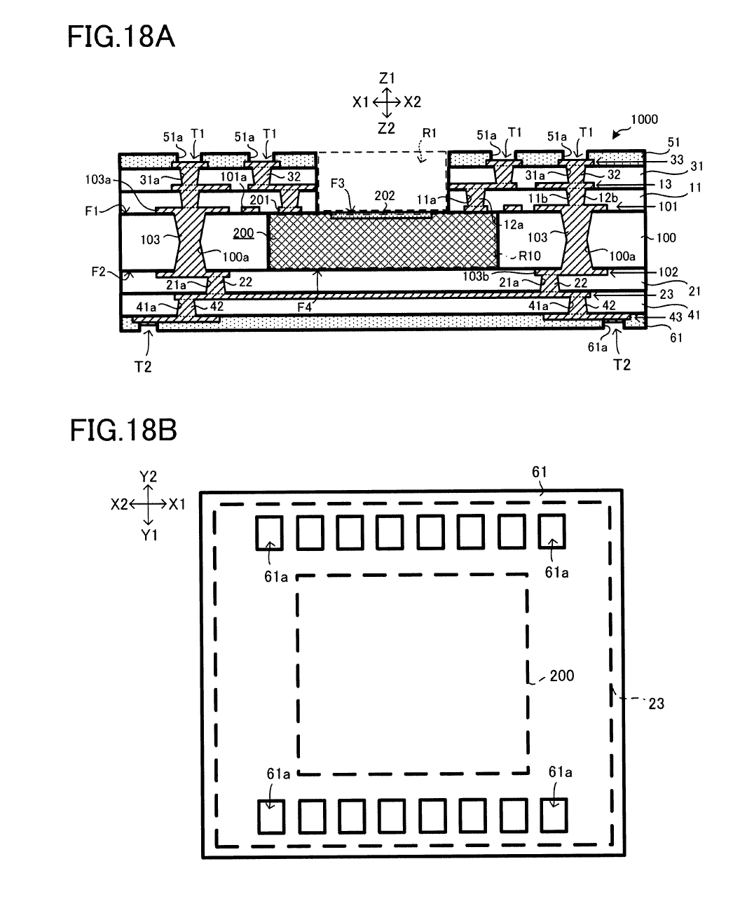

In wiring board 1000 of the present embodiment, outermost conductive layer 43 has a plane conductor. However, the present embodiment is not limited to such. For example, as shown in FIGS. 18A and 18B, conductive layer 23 positioned as a lower layer of conductive layer 43 (an inner conductive layer) may have a plane conductor in the region corresponding to opening portion (R1). Alternatively, both conductive layers 23 and 43 may have a conductive layer in the region corresponding to opening portion (R1).

The plane conductor of the present embodiment has a shape greater than opening portion (R1) and similar to the shape of opening portion (R1) when seen on the X-Y plane. However, the present embodiment is not limited to such. For example, when seen on the X-Y plane, the plane conductor may have substantially the same size and shape as opening portion (R1) and may be positioned at substantially the same location as opening portion (R1).

### Examples

In the following, simulations conducted by the inventors are described. The inventors conducted respectively a simulation on a wiring board with a built-in imaging element relating to the embodiments of the present invention and on a wiring board with a built-in imaging element relating to a comparative example.

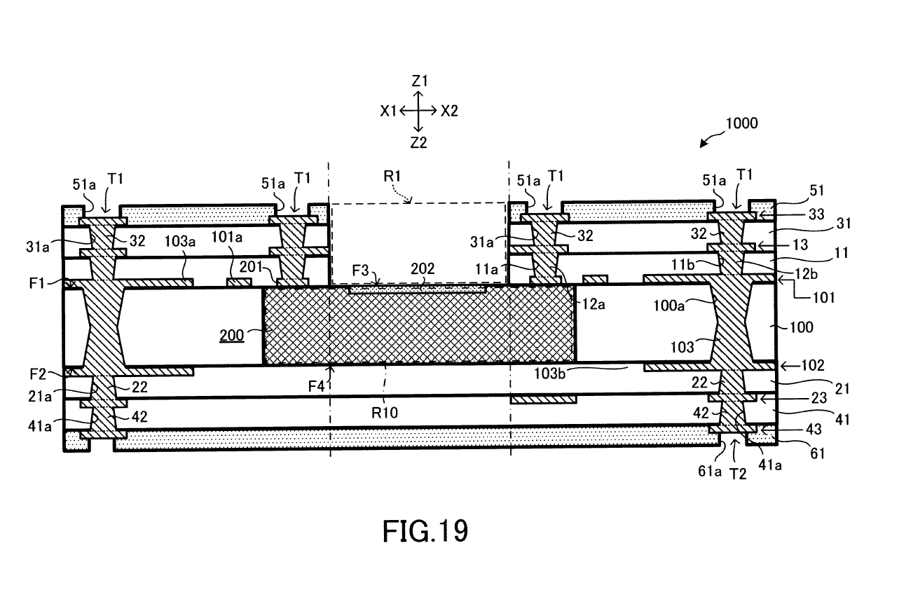

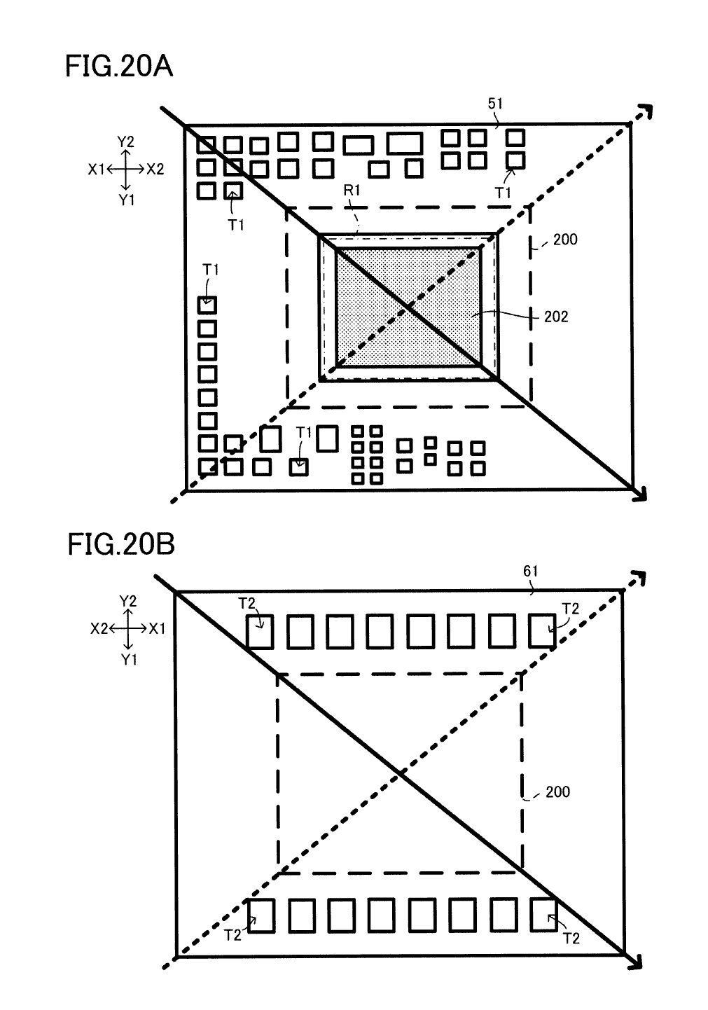

The structure of the samples for the simulations is shown in FIGS. 19-20B. In FIGS. 19-20B, the same numerical reference is applied to the corresponding identical element as shown in above FIG. 1 and others.

Two insulation layers (11, 31) and two conductive layers (13, 33) are alternately laminated on the first-surface (F1) side of substrate 100, and two insulation layers (21, 41) and two conductive layers (23, 43) are alternately laminated on the second-surface (F2) side of substrate 100 in the samples, the same as in wiring board 1000 shown in FIG. 1. Via conductors (12a, 12b) are formed in insulation layer 11, and via conductors (22, 32, 42) are formed in insulation layers (21, 31, 41) respectively. Via conductors (12a, 12b, 22, 32, 42) electrically connect their respective upper and lower conductive layers through an interlayer insulation layer. In addition, through-hole conductor 103 is formed in substrate 100, and conductive layers (101, 102) on both surfaces of substrate 100 are electrically connected to each other by through-hole conductor 103.

Via conductors (12a, 12b, 22, 32, 42) are each a filled conductor. In the sample, via conductors (12a, 12b) and via conductor 32 are stacked, and via conductor 22 and via conductor 42 are stacked.

Solder resist 51 is formed on the first-surface (F1) side surface of wiring board 1000, and solder resist 61 is formed on the second-surface (F2) side surface of wiring board 1000. On outermost conductive layer 33, the portion exposed through opening portion (51a) of solder resist 51 is set as external connection terminal (T1). In addition, on outermost conductive layer 43, the portion exposed through opening portion (61a) of solder resist 61 is set as external connection terminal (T2). External connection terminals (T1, T2) of wiring board 1000 are each a pad.

In substrate 100, opening portion (R10) is formed as a hole that penetrates through substrate 100. In addition, imaging element 200 is positioned in opening portion (R10) in such a way that third surface (F3) faces in the same direction as first surface (F1) of substrate 100. Substantially the entire imaging element 200 is completely accommodated in opening portion (R10). Also, opening portion (R1) for exposing light receiver 202 of imaging element 200 is formed in insulation layer 11, insulation layer 31 and solder resist 51. Opening portion (R1) is a hole that penetrates through insulation layer 11, insulation layer 31 and solder resist 51 and reaches light receiver 202 of imaging element 200. Opening portion (R1) has a shape corresponding to light receiver 202 and mostly exposes only light receiver 202.

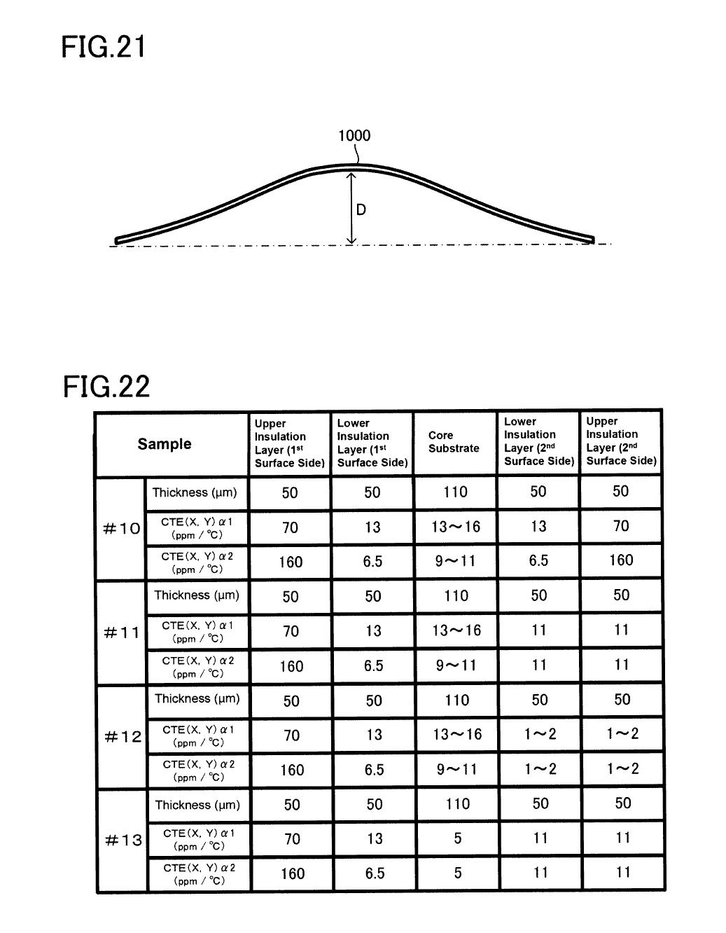

The inventors conducted simulations on the samples (wiring boards 1000) having the above structure. Specifically, temperatures of wiring board 1000 were changed from 180° C. to 25° C. when there was no warping in the wiring board. The amount of warping (D) as shown in FIG. 21 was measured along each diagonal line (see FIGS. 20A and 20B) on the upper and lower surfaces of wiring board 1000 (main surface on the first-surface (F1) side or main surface on the second-surface (F2) side), and the average value of the amount of warping (D) (hereinafter simply referred to as the amount of warping) along each diagonal line was obtained.

The first simulation is described as follows.

FIG. 22 shows structures of samples #10, #11, #12 and #13 in the first simulation. In FIG. 22, “CTE (X, Y) α1” means a thermal expansion coefficient in directions (X, Y) in a temperature range at or less than the glass transition temperature (hereinafter referred to as “Tg”); and “CTE (X, Y) α2” means a thermal expansion coefficient in directions (X, Y) in a temperature range at or greater than the Tg. In the following, “CTE (X, Y) α1” and “CTE (X, Y) α2” are referred to simply as “CTE α1” and “CTE α2” respectively.

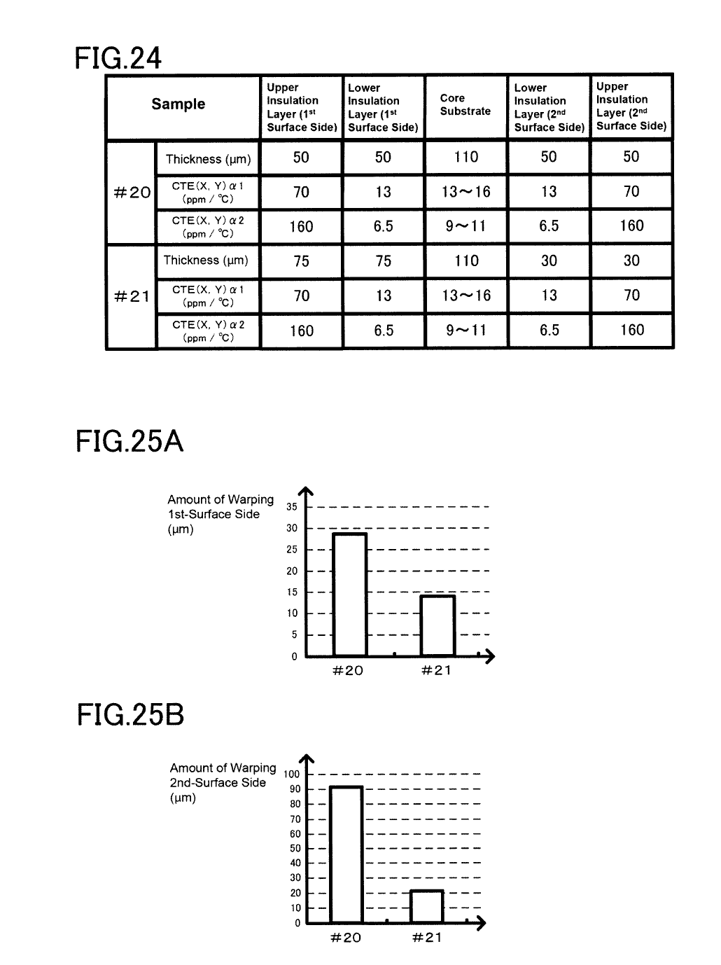

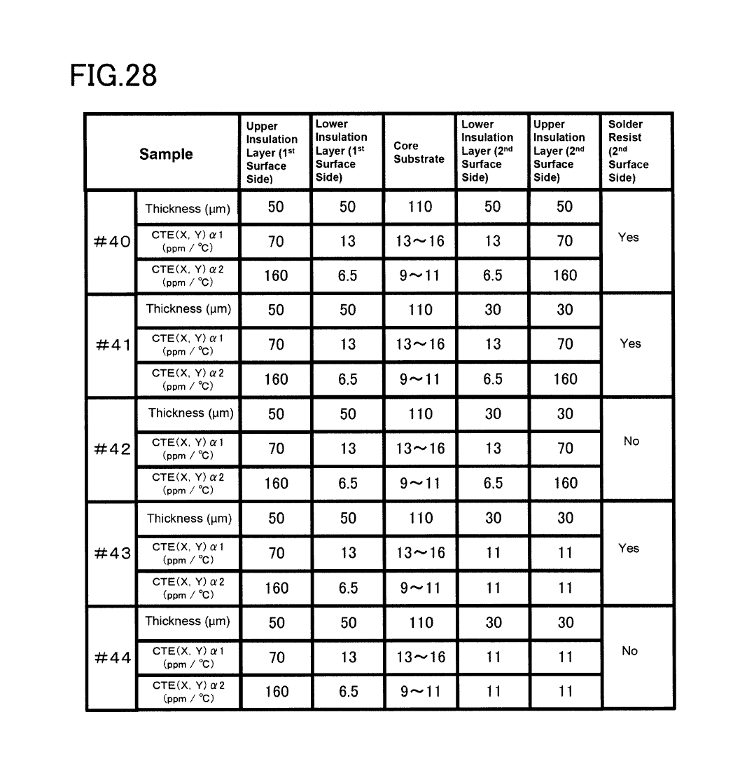

Samples #10˜#13 each have the structure shown previously in FIG. 19. In FIG. 22, upper insulation layer (first-surface side), lower insulation layer (first-surface side), core substrate, lower insulation layer (second-surface side) and upper insulation layer (second-surface side) correspond respectively to insulation layer 31, insulation layer 11, substrate 100, insulation layer 21 and insulation layer 41 in FIG. 19. The same applies to later-described FIGS. 24 and 28.

When samples #10˜#13 of the present simulation are compared with each other, as shown in FIG. 22, among the samples there is no difference in the thicknesses of the core substrate and each insulation layer along with “CTE α1” and “CTE α2” of insulation layer 31 and insulation layer 11. In particular, the thicknesses of insulation layer 31, insulation layer 11, insulation layer 21 and insulation layer 41 are each 50 μm, and the thickness of substrate 100 is 110 μm in each sample. In addition, in each sample, “CTE α1” and “CTE α2” of insulation layer 31 are 70 ppm/° C. and 160 ppm/° C. respectively; and “CTE α1” and “CTE α2” of insulation layer 11 are 13 ppm/° C. and 6.5 ppm/° C. respectively. The Tg of insulation layer 31 is 165° C. and the Tg of insulation layer 11 is 145° C.

In the first simulation, the change in the amount of warping is examined when “CTE α1” and “CTE α2” of substrate 100, insulation layer 21 and insulation layer 41 are modified. In samples #10˜#13 of the present simulation, “CTE α1” and “CTE α2” in substrate 100, insulation layer 21 and insulation layer 41 respectively have the following values.

In sample #10, “CTE α1” and “CTE α2” of substrate 100 are 13˜16 ppm/° C. and 9˜11 ppm/° C. respectively; “CTE α1” and “CTE α2” of insulation layer 21 are 13 ppm/° C. and 6.5 ppm/° C. respectively; and “CTE α1” and “CTE α2” of insulation layer 41 are 70 ppm/° C. and 160 ppm/° C. respectively. Here, the Tg of substrate 100 is 156° C. and the Tg of insulation layer 21 is 145° C. When identical ordinal numbers counted from substrate 100 are compared, the thermal expansion coefficient of insulation layer 21 is the same as the thermal expansion coefficient of insulation layer 11 at the first layers from substrate 100; the thermal expansion coefficient of insulation layer 41 is the same as the thermal expansion coefficient of insulation layer 31 at the second layers from substrate 100.

In sample #11, “CTE α1” and “CTE α2” of substrate 100 are 13˜16 ppm/° C. and 9˜11 ppm/° C. respectively; “CTE α1” and “CTE α2” of insulation layer 21 are 11 ppm/° C. and 11 ppm/° C. respectively; and “CTE α1” and “CTE α2” of insulation layer 41 are 11 ppm/° C. and 11 ppm/° C. respectively. Here, the Tg of substrate 100 is 156° C.

In sample #12, “CTE α1” and “CTE α2” of substrate 100 are 13˜16 ppm/° C. and 9˜11 ppm/° C. respectively; “CTE α1” and “CTE α2” of insulation layer 21 are 1˜2 ppm/° C. and 1˜2 ppm/° C. respectively; and “CTE α1” and “CTE α2” of insulation layer 41 are 1˜2 ppm/° C. and 1˜2 ppm/° C. respectively. Here, the Tg of substrate 100 is 156° C.

In sample #13, “CTE α1” and “CTE α2” of substrate 100 are 5 ppm/° C. and 5 ppm/° C. respectively; “CTE α1” and “CTE α2” of insulation layer 21 are 11 ppm/° C. and 11 ppm/° C. respectively; and “CTE α1” and “CTE α2” of insulation layer 41 are 11 ppm/° C. and 11 ppm/° C. respectively.

Samples #11˜#13 have substantially the same structure as the wiring board with a built-in imaging element according to the first embodiment.

In sample #12, each “CTE α1” of insulation layers (21, 41) is lower than any “CTE α1” of insulation layers (11,31), and each “CTE α2” of insulation layers (21, 41) is lower than any “CTE α2” of insulation layers (11, 31). Namely, when identical ordinal numbers counted from substrate 100 are compared, at the first layers counted from substrate 100, the thermal expansion coefficient of insulation layer 21 is lower than the thermal expansion coefficient of insulation layer 11; and at the second layers counted from substrate 100, the thermal expansion coefficient of insulation layer 41 is lower than the thermal expansion coefficient of insulation layer 31.

In samples #11 and #13, “CTE α2” of insulation layer 21 is higher than “CTE α2” of insulation layer 11, but “CTE α1” of insulation layer 21 is lower than “CTE α1” of insulation layer 11. Also, “CTE α1” of insulation layer 41 is lower than “CTE α1” of insulation layer 31, and “CTE α2” of insulation layer 41 is lower than “CTE α2” of insulation layer 31. Namely, when identical ordinal numbers counted from substrate 100 are compared, at the first layers from substrate 100, the thermal expansion coefficient (CTE α1) of insulation layer 21 is lower than the thermal expansion coefficient (CTE α1) of insulation layer 11; and at the second layers from substrate 100, the thermal expansion coefficient of insulation layer 41 is lower than the thermal expansion coefficient of insulation layer 31.

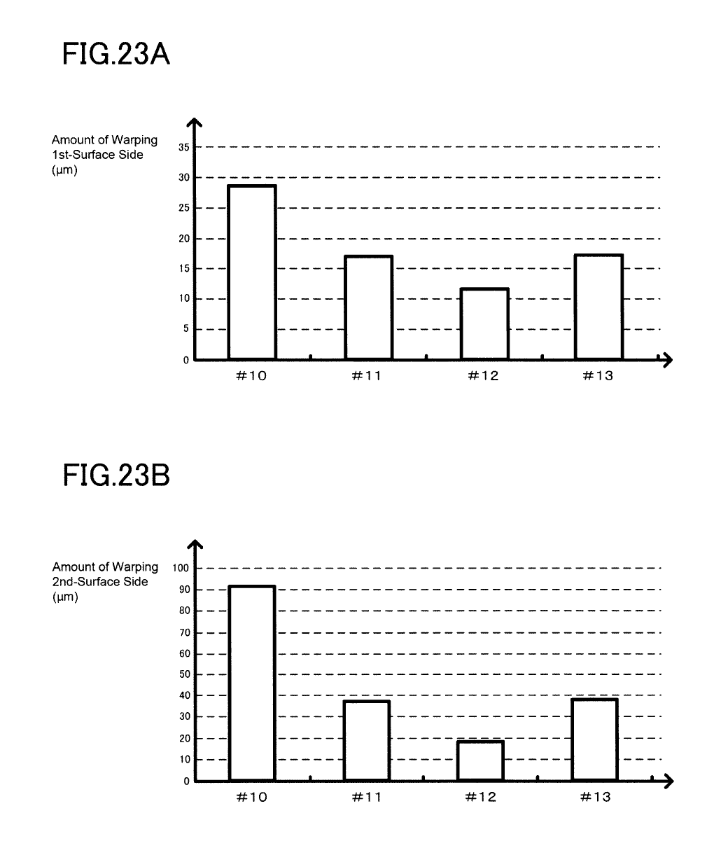

FIGS. 23A and 23B show simulation results in the amounts of warping in above samples #10˜#13 respectively. FIG. 23A is a graph showing the amounts of warping of main surfaces on the first-surface (F1) side, and FIG. 23B is a graph showing the amounts of warping of main surfaces on the second-surface (F2) side.

As shown in FIG. 23A, the amount of warping of a main surface on the first-surface (F1) side is as follows: the amount of warping in sample #10 is 28.6 μm; the amount of warping in sample #11 is 16.9 μm; the amount of warping in sample #12 is 11.6 μm; and the amount of warping in sample #13 is 17.1 μm. Also, as shown in FIG. 23B, the amount of warping of a main surface on the first-surface (F2) side is as follows: the amount of warping in sample #10 is 91.7 μm; the amount of warping in sample #11 is 37.3 μm; the amount of warping in sample #12 is 18.4 μm; and the amount of warping in sample #13 is 38.2 μm.

As described above, the amounts of warping in samples #11˜#13 were smaller than the amount of warping in sample #10. Especially, the sample which showed the smallest amount of warping was sample #12. Therefore, to reduce the amount of warping, it is preferable if the thermal expansion coefficient of an insulation layer laminated on second surface (F2) of substrate 100 (second insulation layer) is set lower than the thermal expansion coefficient of an insulation layer laminated on first surface (F1) of substrate 100 (first insulation layer) at least at one ordinal number when identical ordinal numbers counted from substrate 100 are compared. In addition, when identical ordinal numbers counted from substrate 100 are compared, if the thermal expansion coefficients of interlayer insulation layers (insulation layers 21, 41) laminated on second surface (F2) of substrate 100 are set lower than the thermal expansion coefficients of interlayer insulation layers (insulation layers 11, 31) laminated on first surface (F1) of substrate 100 at all the ordinal numbers, the effect on warping reduction is enhanced. According to such a structure, the amount of warping during the manufacturing process (especially during thermal treatment process) is reduced in a wiring board.

Since the amounts of warping in samples #11 and #12 were smaller than the amount of warping in sample #10, to reduce the amount of warping, it is especially preferable if “CTE α1” (the CTE in directions XY in a temperature range at or less than the glass transition temperature) of an insulation layer (second insulation layer) laminated on second surface (F2) of substrate 100 is set lower than “CTE α1” of an insulation layer (first insulation layer) laminated on first surface (F1) of substrate 100 at least at one ordinal number when identical ordinal numbers counted from substrate 100 are compared. In addition, when identical ordinal numbers counted from substrate 100 are compared, it is more effective if, at all the ordinal numbers, “CTE α1” of interlayer insulation layers (insulation layers 21, 41) laminated on second surface (F2) of substrate 100 is set lower than “CTE α1” of interlayer insulation layers (insulation layers 11, 31) laminated on first surface (F1) of substrate 100.

The second simulation is described.

FIG. 24 shows the structures of samples #20 and #21 in the second simulation. Samples #20 and #21 both have the structure shown previously in FIG. 19.

When samples #20 and #21 of the present simulation are compared with each other, “CTE α1” and “CTE α2” of the core substrate and each insulation layer show no difference between the samples as shown in FIG. 24. In particular, in each sample, “CTE α1” and “CTE α2” of insulation layer 31 or 41 are 70 ppm/° C. and 160 ppm/° C. respectively; “CTE α1” and “CTE α2” of insulation layer 11 or 21 are 13 ppm/° C. and 6.5 ppm/° C. respectively; and “CTE α1” and “CTE α2” of core substrate 100 are 13˜16 ppm/° C. and 9˜11 ppm/° C. respectively. The Tg of insulation layers (31, 41) is 165° C., the Tg of insulation layers (11, 21) is 145° C. and the Tg of substrate 100 is 156° C.

In the second simulation, the change in the amount of warping is examined when thicknesses of insulation layers (11, 21, 31, 41) are modified. In samples #20 and #21 in the present simulation, the thicknesses of insulation layers (11, 21, 31, 41) have the following values.

In sample #20, the thicknesses of insulation layer 31, insulation layer 11, insulation layer 21 and insulation layer 41 are each 50 μm and the thickness of substrate 100 is 110 μm. When identical ordinal numbers counted from substrate 100 are compared, at the first layers from substrate 100, the thickness of insulation layer 21 is the same as the thickness of insulation layer 11; and at the second layers from substrate 100, the thickness of insulation layer 41 is the same as the thickness of insulation layer 31.

In sample #21, the thicknesses of insulation layer 31 and insulation layer 11 are each 75 μm, the thicknesses of insulation layer 21 and insulation layer 41 are each 30 μm, and the thickness of substrate 100 is 110 μm. Namely, when identical ordinal numbers counted from substrate 100 are compared, at the first layers from substrate 100, the thickness of insulation layer 21 is less than the thickness of insulation layer 11; and at the second layers from substrate 100, the thickness of insulation layer 41 is less than the thickness of insulation layer 31.

Sample #21 has a structure substantially the same as a wiring board with a built-in imaging element according to the second embodiment.

In sample #21, the thicknesses of insulation layers (21, 41) are each less than any of the thicknesses of insulation layers (11, 31). In addition, the sum of thicknesses of interlayer insulation layers (insulation layers 21, 41) laminated on the second-surface (F2) side of substrate 100 is 60 μm, which is smaller than the sum of thicknesses (150 μm) of interlayer insulation layers (insulation layers 11, 31) laminated on the first-surface (F1) side of substrate 100.

FIGS. 25A and 25B show simulation results in the amounts of warping in above samples #20 and #21 respectively. FIG. 25A is a graph showing the amounts of warping of main surfaces on the first-surface (F1) side, and FIG. 25B is a graph showing the amounts of warping of main surfaces on the second-surface (F2) side.

As shown in FIG. 25A, regarding the amount of warping of a main surface on the first-surface (F1) side, the amount of warping in sample #20 is 28.6 μm, and the amount of warping in sample #21 is 13.8 82 m. Also, as shown in FIG. 25B, regarding the amount of warping of a main surface on the second-surface (F2) side, the amount of warping in sample #20 is 91.7 μm, and the amount of warping in sample #21 is 21.5 μm.

As described above, the amount of warping in sample #21 was smaller than the amount of warping in sample #20. Therefore, to reduce the amount of warping, it is preferable if the thickness of the insulation layer (second insulation layer) laminated on second surface (F2) of substrate 100 is set less than the thickness of the insulation layer (first insulation layer) laminated on first surface (F1) of substrate 100 at least at one ordinal number (more preferably, at all the ordinal numbers) when identical ordinal numbers counted from substrate 100 are compared. In addition, it is especially effective if the sum of thicknesses of interlayer insulation layers (insulation layers 21, 41) on the second-surface (F2) side of substrate 100 is set smaller than the sum of thicknesses of interlayer insulation layers (insulation layers 11, 31) on the first-surface (F1) side of substrate 100.

The third simulation is described.

In the third simulation, the amount of warping is examined to see how it changes depending on whether or not solder resist exists or when the way the solder resist is formed is changed.

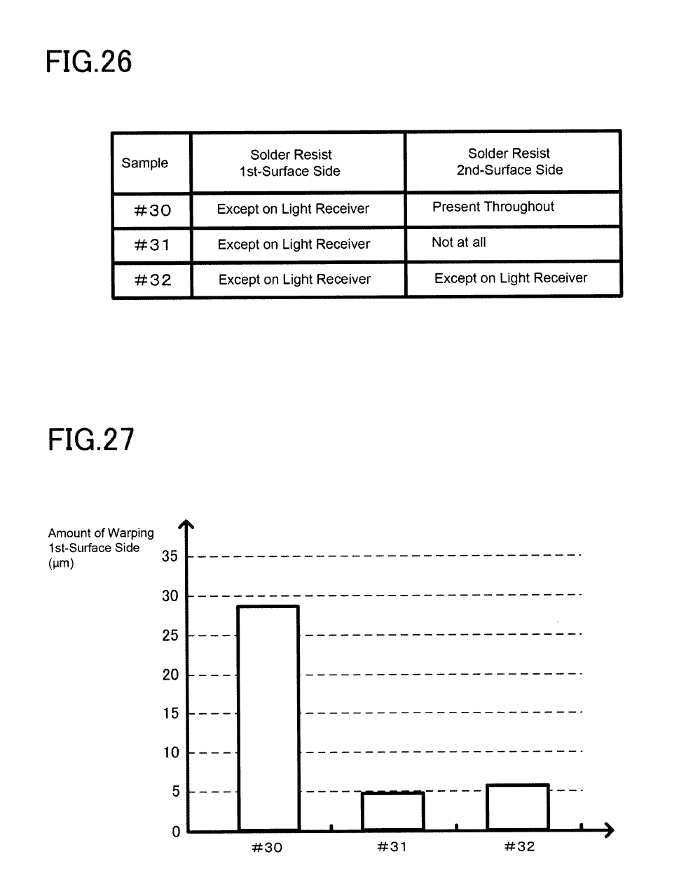

FIG. 26 shows the structures of samples #30˜#32 in the third simulation. Samples #30˜#32 each have substantially the same structure as that shown previously in FIG. 19. However, sample #31 does not have solder resist 61 (solder resist on the second-surface (F2) side). In addition, the same as in the wiring board with a built-in imaging element according to the third embodiment, a portion corresponding to opening portion (R1) (light receiver 202) is completely removed from solder resist 61 in sample #32, to form opening portion (R2) (see FIG. 13). Namely, in sample #32, the third-surface (F3) side of imaging element 200 is symmetrical with the fourth-surface (F4) side of imaging element 200.

FIG. 27 shows simulation results of the amounts of warping in above samples #30˜#32 respectively. FIG. 27 is a graph showing the amounts of warping of main surfaces on the first-surface (F1) side.

As shown in FIG. 27, the amount of warping in sample #30 is 28.6 μm, the amount of warping in sample #31 is 4.9 μm, and the amount of warping in sample #32 is 6.1 μm.

As described above, the amounts of warping in sample #31 and #32 were smaller than the amount of warping in sample #30. Accordingly, to reduce the amount of warping, it is effective if solder resist 61 formed on the second-surface (F2) side of substrate 100 is removed.

In addition, since the amount of warping in sample #32 is reduced to one quarter or less of the amount of warping in sample #30, the entire solder resist formed on the second-surface (F2) side of substrate 100 is not required to be removed and the amount of warping is significantly reduced by removing only a portion corresponding to opening portion (R1) (light receiver 202) from solder resist 61. According to such a structure, the reliability of electrical connections is enhanced in external connection terminal (T2) on the second-surface (F2) side using the remaining portion of solder resist 61 (the portion that is not removed).

In addition, considering the effect on suppressing warping in a symmetrical structure, to reduce the amount of warping, it is effective if a portion on the surface (main surface) of the second-surface (F2) side corresponding to opening portion (R1) is set thinner than its surroundings. It is especially effective if a portion of solder resist layer 61 corresponding to opening portion (R1) is set thinner than its surroundings.

The fourth simulation is described.

FIG. 28 shows the structures of samples #40, #41, #42, #43 and #44 in the fourth simulation. Samples #40˜#44 each have substantially the same structure as that shown previously in FIG. 19.

When samples #40˜#44 of the present simulation are compared with each other, among the samples there is no difference in the thicknesses, “CTE α1” and “CTE α2” of insulation layer 31, insulation layer 11 and substrate 100, as shown in FIG. 28. Specifically, thicknesses of insulation layer 31 and insulation layer 11 are each 50 μm and the thickness of substrate 100 is 110 μm in each sample. In addition, in each sample, “CTE α1” and “CTE α2” of insulation layer 31 are 70 ppm/° C. and 160 ppm/° C. respectively; “CTE α1” and “CTE α2” of insulation layer 11 are 13 ppm/° C. and 6.5 ppm/° C. respectively; and “CTE α1” and “CTE α2” of substrate 100 are 1316 ppm/° C. and 9˜11 ppm/° C. respectively. The Tg of insulation layer 31 is 165° C., the Tg of insulation layer 11 is 145° C., and the Tg of substrate 100 is 156° C.

In the fourth simulation, the amount of warping is examined to see how it changes depending on the thicknesses of insulation layers 21 and 41, the values of “CTE α1” and “CTE α2” and whether or not solder resist 61 exists. Details of samples #40˜#44 of the present simulation are described as follows.

In sample #40, thicknesses of insulation layer 21 and insulation layer 41 are each 50 μm. In addition, “CTE α1” and “CTE α2” of insulation layer 21 are 13 ppm/° C. and 6.5 ppm/° C. respectively; “CTE α1” and “CTE α2” of insulation layer 41 are 70 ppm/° C. and 160 ppm/° C. respectively. Sample #40 has solder resist 61. The Tg of insulation layer 21 is 145° C. and the Tg of insulation layer 41 is 165° C.

In sample #41, thicknesses of insulation layer 21 and insulation layer 41 are each 30 μm. In addition, “CTE α1” and “CTE α2” of insulation layer 21 are 13 ppm/° C. and 6.5 ppm/° C. respectively; “CTE α1” and “CTE α2” of insulation layer 41 are 70 ppm/° C. and 160 ppm/° C. respectively. Sample #41 has solder resist 61. The Tg of insulation layer 21 is 145° C. and the Tg of insulation layer 41 is 165° C.

Sample #42 has a structure substantially the same as that of sample #41. However, sample #42 does not have solder resist 61.

In sample #43, thicknesses of insulation layer 21 and insulation layer 41 are each 30 μm, and “CTE α1” and “CTE α2” of insulation layer 21 and insulation layer 41 are 11 ppm/° C. and 11 ppm/° C. respectively. Sample #43 has solder resist layer 61.

Sample #44 has a structure substantially the same as that of sample #43. However, sample #44 does not have solder resist 61.

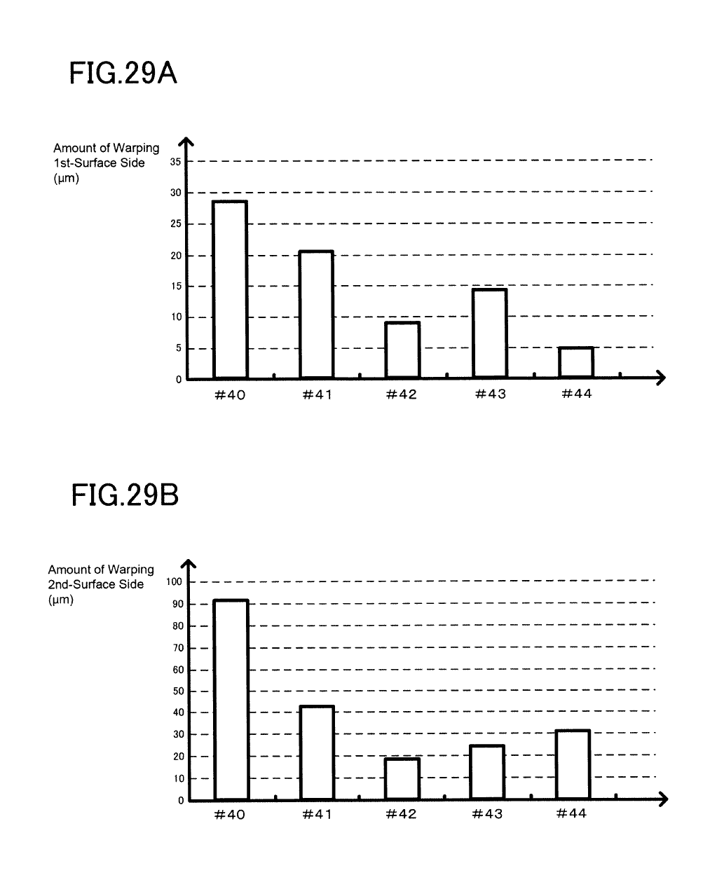

FIGS. 29A and 29B show the simulation results of the amounts of warping in above samples #40˜#44 respectively. FIG. 29A is a graph showing the amounts of warping of main surfaces on the first-surface (F1) side, and FIG. 29B is a graph showing the amounts of warping of main surfaces on the second-surface (F2) side.

As shown in FIG. 29A, regarding the amount of warping of a main surface on the first-surface (F1) side, the amount of warping of sample #40 is 28.6 μm, the amount of warping of sample #41 is 20.7 μm, the amount of warping of sample #42 is 9.1 μm, the amount of warping of sample #43 is 14.3 μm, and the amount of warping of sample #44 is 4.9 μm. Also, as shown in FIG. 29B, regarding the amount of warping of a main surface on the second-surface (F2) side, the amount of warping of sample #40 is 91.7 μm, the amount of warping of sample #41 is 42.9 μm, the amount of warping of sample #42 is 18.5 μm, the amount of warping of sample #43 is 24.2 μm, and the amount of warping of sample #44 is 31.4 μm.

From the above results, the effect on reducing the amount of warping is enhanced by combining the structures in the first embodiment through the third embodiment.

### Other Embodiments

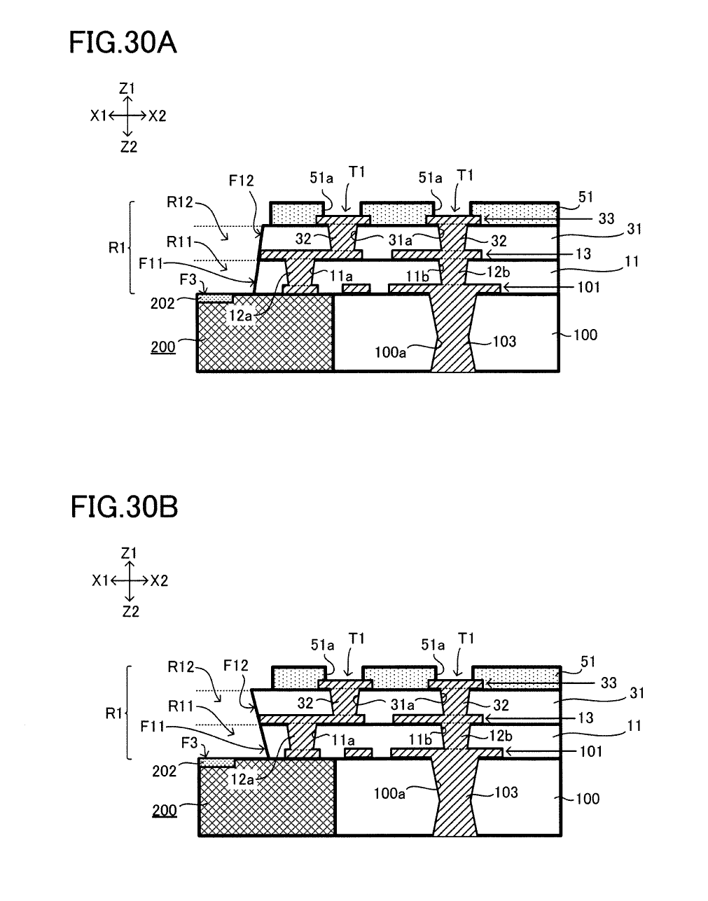

The plane made by a side surface of insulation layer 11 facing opening portion (R11) and by a side surface of insulation layer 31 facing opening portion (R12) may be a slope inclined at an obtuse angle or an acute angle against third surface (F3) (sensor surface) of imaging element 200 as shown in FIGS. 30A and 30B, for example. Opening portion (R12) of insulation layer 31 may have a greater width than opening portion (R11) of insulation layer 11 (see FIG. 30A), or may have a smaller width than opening portion (R11) of insulation layer 11 (see FIG. 32B).

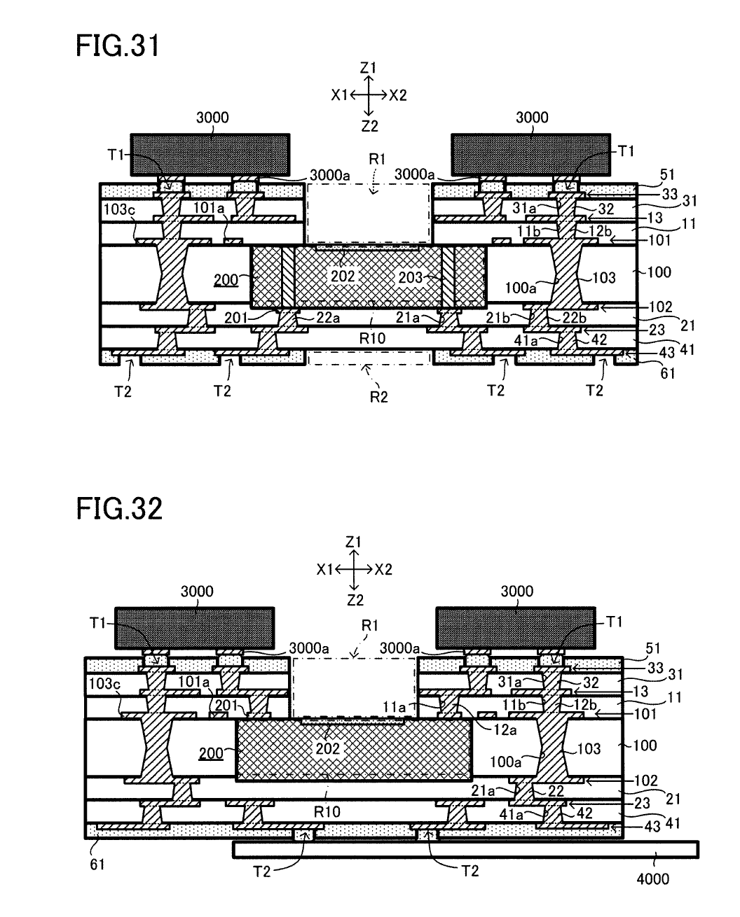

As shown in FIG. 31, imaging element 200 may have light receiver 202 on the side opposite electrode 201. Imaging element 200 shown in FIG. 31 has TSV (through silicon via) 203 along with light receiver 202 on one side and electrode 201 on the other side. Electrode 201 and light receiver 202 are electrically connected to each other via TSV 203. In addition, holes (21a, 21b) (via holes) are formed in insulation layer 21, and by filling conductor (such as copper plating) respectively in holes (21a, 21b), conductors in holes (21a, 21b) become via conductors (22a, 22b) (filled conductors) respectively. Electrode 201 and external connection terminal (T2) are electrically connected to each other through via conductors (22a, 42), and through-hole conductor 103 and external connection terminal (T2) are electrically connected to each other through via conductors (22b, 42).

In the above embodiments, a motherboard is connected to external connection terminal (T2). However, a wiring board other than a motherboard may be connected to external connection terminal (T2). For example, as shown in FIG. 32, external connection terminal (T2) of a wiring board with a built-in imaging element may be electrically connected to an external connection terminal of flexible wiring board 4000. They may be connected by soldering, for example.

Opening portions (R1, R10) are not limited to being holes, and they may be grooves, notches, slits or the like.

The position of light receiver 202 is not limited to the central portion of imaging element 200, and may be in any other position. For example, light receiver 202 may be positioned closer to any of the four sides of imaging element 200.

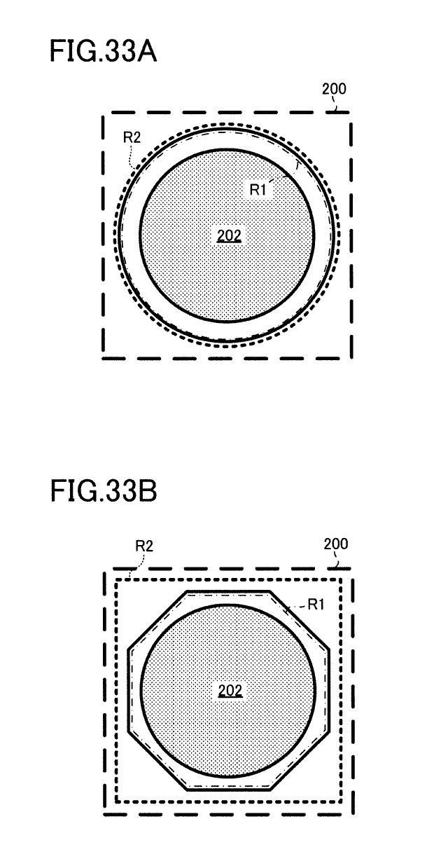

The shape of light receiver 202 and the shape of horizontal cross sections (X-Y plane) of opening portions (R1, R2) are not limited to being substantially rectangular, and may be any other shape. The shape of those surfaces may be substantially circular (substantially a complete circle) as shown in FIG. 33A, for example. In addition, other than substantially rectangular, the shape may be substantially polygonal, for example, substantially hexagonal, substantially octagonal or the like. Here, the angles of a polygon are not limited to any specific shape, and they may be substantially right, acute or obtuse, or they may be roundish. Moreover, the shape of light receiver 202 and the shape of horizontal cross sections (X-Y plane) of opening portions (R1, R2) may be substantially elliptic or substantially triangular. Alternatively, their shapes may be substantially a cross or substantially a regular polygonal star formed by drawing straight lines to radiate out from the center (shapes in which multiple spokes are positioned in a radial pattern).

Alternatively, as shown in FIG. 33B, the shape of light receiver 202 and the shape of horizontal cross sections (X-Y plane) of opening portions (R1, R2) may be different from each other. In the example in FIG. 33B, light receiver 202 was shaped as substantially a complete circle, the horizontal cross section of opening portion (R1) as substantially an octagon, and the horizontal cross section of opening portion (R2) as substantially a square. In such a case as well, if opening portion (R2) is formed in a location corresponding to opening portion (R1) (the location overlapping opening portion (R1)), the above effect on suppressing warping is achieved.

Other than the above, imaging element 200 and opening portion (R10) may be shaped freely.

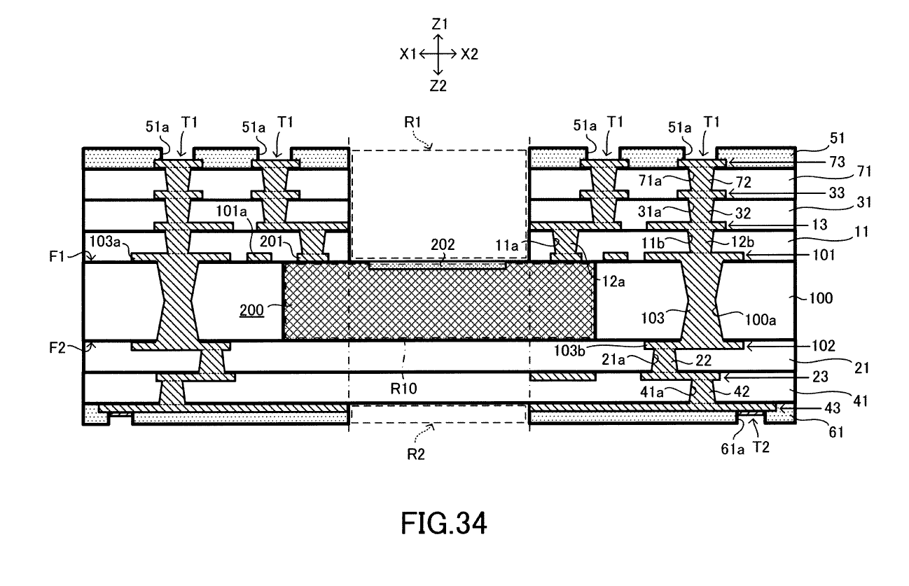

A wiring board with a built-in imaging element may have three or more buildup layers. For example, as shown in FIG. 34, it is an option that three insulation layers (11, 31, 71) and three conductive layers (13, 33, 73) are alternately laminated on the first-surface (F1) side of substrate 100, and two insulation layers (21, 41) and two conductive layers (23, 43) are alternately laminated on the second-surface (F2) side of substrate 100. In the example in FIG. 34, hole (71a) (via hole) is formed in insulation layer 71, and by filling conductor (such as copper plating) in hole (71a), the conductor in hole (71a) becomes via conductor 72 (filled conductor). Conductive layer 33 on insulation layer 31 and conductive layer 73 on insulation layer 71 are electrically connected to each other through via conductor 72. A hole (opening portion (R1)) is formed to penetrate through insulation layers (11, 31, 71) and to reach light receiver 202 of imaging element 200, and light receiver 202 is exposed through the hole.

In addition, the number of buildup layers may be different on the first-surface (F1) side of substrate 100 and on the second-surface (F2) side of substrate 100. For example, as shown in FIG. 34, the number (three) of insulation layers laminated on the second-surface (F2) side of substrate 100 (insulation layers (21, 41) and solder resist 61) may be less than the number (four) of insulation layers laminated on the first-surface (F1) side of substrate 100 (insulation layers (11, 31, 71) and solder resist 51). Although the symmetry of the upper and lower surfaces of substrate 100 decreases when opening portion (R1) is formed, if the number of insulation layers on the first-surface (F1) side of substrate 100 is set greater than on the second-surface (F2) side of substrate 100, such as the structure shown in FIG. 34, the symmetry of the upper and lower surfaces of substrate 100 is enhanced and warping is suppressed in the wiring board. Also, if the total number of insulation layers is set the same on the first-surface (F1) side of substrate 100 and on the second-surface (F2) side of substrate 100, such as the structure as shown in FIG. 1, for example, warping may occur in the wiring board during a step for curing the resin (see FIGS. 7-8) or the like. When warping occurs, there may be occasions when the wiring board is required to be made flat by pressing it with a jig or the like during the later step of laser irradiation (see FIG. 10). For that matter, according to the structure shown in FIG. 34, since the amount of warping during laser irradiation decreases in the wiring board, it is easier to manufacture wiring boards. In the example in FIG. 34, opening portion (R2) is formed in solder resist 61, but it is also an option to have a structure that does not have opening portion (R2).

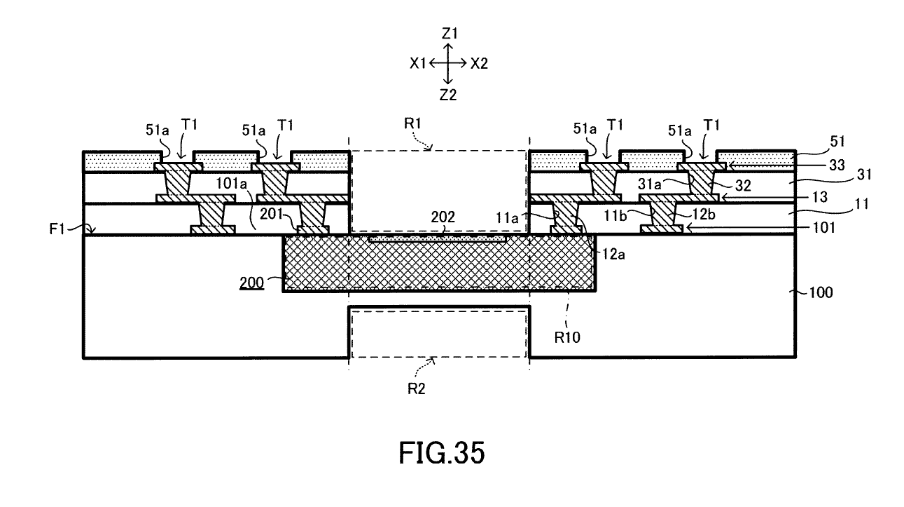

In the above embodiments, a double-sided wiring board (wiring board 1000) was shown. However, the wiring board is not limited to such, and it may be a single-sided wiring board, as shown in FIG. 35, for example. In such a case, the amount of warping is also reduced if the location corresponding to opening portion (R1) on the second-surface (F2) side surface of substrate 100 is made thinner than its surroundings. Substrate 100 may be made partially thinner by a lithographic technique, for example.

In addition, as shown in FIG. 35, for example, opening portion (R10) (accommodation space for imaging element 200) may be a hole that does not penetrate through substrate 100 (a recessed portion). In such a case, it is also preferred that the thickness of imaging element 200 and the depth of opening portion (R10) (hole) be substantially the same.

In the above embodiments, an example was shown in which the thickness of substrate 100 and the thickness of imaging element 200 are substantially the same. However, the present invention is not limited to the above. For example, as shown in FIG. 35, the thickness of substrate 100 may be greater than the thickness of imaging element 200.

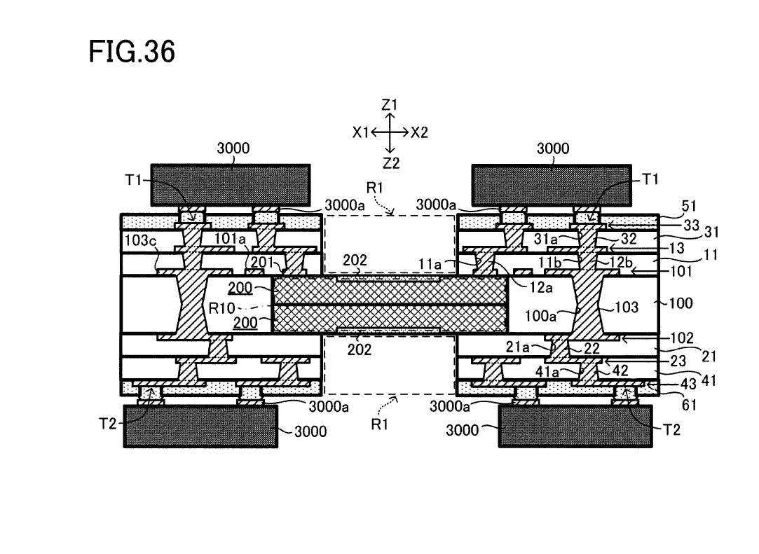

The above embodiments described a wiring board with a built-in imaging element (wiring board 1000) having a sensor surface (light receiver 202) only on one surface. However, the present invention is not limited to the above. For example, as shown in FIG. 36, a wiring board with a built-in imaging element may have a sensor surface on both surfaces. In the example in FIG. 36, opening portion (R1) is formed on both surfaces, and each sensor surface (light receiver 202) is exposed.

The above embodiments described a wiring board with a built-in imaging element (wiring board 1000) having only one imaging element 200 in opening portion (R10) (accommodation space for imaging element 200). However, the present invention is not limited to the above. For example, as shown in FIG. 36, a wiring board with a built-in imaging element may have multiple imaging elements 200 in opening portions (R0). In the example in FIG. 36, multiple imaging elements 200 are arrayed in lamination directions (directions Z). However, multiple imaging elements 200 may be positioned side by side in a direction X or a direction Y.

Regarding other factors such as the structure of the above wiring board 1000 (wiring board with a built-in imaging element), the type of its structural elements, quality, dimensions, material, shape, number of layers, position and the like may be freely modified within a scope that does not deviate from the gist of the present invention.

For example, via conductors (12a, 12b, 22, 32, 42, 72) are not limited to being filled conductors, and they may also be conformal conductors, for example.

Moreover, insulation layer 11 is not always required to be formed on imaging element 200. It is also an option not to mount imaging element 200 through via connection (via conductor 12a), but to use other methods such as wire bonding.

In addition, in wiring boards with a built-in imaging element according to the above embodiments, it is also an option to have a structure where among the holes formed in insulation layers (11, 31), a hole that penetrates through both insulation layers (11, 31) is the only hole for exposing light receiver 202 of imaging element 200 (opening portion (R1)).

Also, in wiring boards with a built-in imaging element according to the above embodiments, it is also an option to have a structure where among the holes formed in insulation layers (11, 31), the largest hole is the hole for exposing light receiver 202 of imaging element 200 (opening portion R1).

The method for manufacturing a wiring board is not limited to the order and contents shown in the above embodiments, and the order and contents may be freely modified within a scope that does not deviate from the gist of the present invention. Also, some procedures may be omitted depending on usage or the like.

For example, the method for forming each conductive layer is not limited specifically. For example, conductive layers may be formed by any of the following methods or by combining any two or more methods: panel plating method, pattern plating method, full-additive method, semi-additive (SAP) method, subtractive method, transfer method and tenting method.

Also, instead of using a laser, wet or dry etching may be used for processing. When etching is used, it is preferred, using resist or the like, to protect in advance the portions which are not required to be removed.

Each of the above embodiments and modified examples or the like may be combined freely. It is preferred to select an appropriate combination according to usage or the like. For example, any of the structures shown in FIGS. 30A-308 may be applied to any of the structures shown in FIGS. 31-36. Also, in the example in FIG. 34, when identical ordinal numbers counted from substrate 100 are compared, at least at one ordinal number, the thermal expansion coefficient or the thickness of the insulation layer laminated on second surface (F2) of substrate 100 (second insulation layer) is smaller than the thermal expansion coefficient or the thickness of the insulation layer laminated on first surface (F1) of substrate 100 (first insulation layer), the amount of warping tends to be reduced.

A wiring board with a built-in imaging element according to one aspect of the present invention has the following: a substrate which has a first surface and a second surface opposite the first surface, and in which an opening portion is formed; an imaging element which has a third surface and a fourth surface opposite the third surface, and which has a light receiver on the third-surface side and is positioned in the opening portion in such a way that the third surface faces in the same direction as the first surface; multiple first insulation layers laminated on the first surface of the substrate in such a way to expose the light receiver of the imaging element; and multiple second insulation layers laminated on the second surface of the substrate and on the fourth surface of the imaging element. In such a wiring board, the thermal expansion coefficient of a second insulation layer positioned at a predetermined tier counted from the substrate is set lower than the thermal expansion coefficient of a first insulation layer positioned at the predetermined tier counted from the substrate.

A wiring board with a built-in imaging element according to another aspect of the present invention has the following: a substrate which has a first surface and a second surface opposite the first surface, and in which an opening portion is formed; an imaging element which has a third surface and a fourth surface opposite the third surface, and which has a light receiver on the third-surface side and is positioned in the opening portion in such a way that the third surface faces in the same direction as the first surface; multiple first insulation layers laminated on the first surface of the substrate in such a way to expose the light receiver of the imaging element; and multiple second insulation layers laminated on the second surface of the substrate and on the fourth surface of the imaging element. In such a wiring board, the thickness of a second insulation layer positioned at a predetermined tier counted from the substrate is less than the thickness of a first insulation layer positioned at the predetermined tier counted from the substrate.

A wiring board with a built-in imaging element according to another aspect of the present invention has the following: a substrate which has a first surface and a second surface opposite the first surface, and in which an opening portion is formed; an imaging element which has a third surface and a fourth surface opposite the third surface, and which has a light receiver on the third-surface side and is positioned in the opening portion in such a way that the third surface and the first surface face in the same direction; multiple first insulation layers laminated on the first surface of the substrate in such a way to expose the light receiver of the imaging element; and multiple second insulation layers laminated on the second surface of the substrate and on the fourth surface of the imaging element. In such a wiring board, the number of the second insulation layers is less than the number of the first insulation layers.

A wiring board with a built-in imaging element according to another aspect of the present invention has the following: a substrate which has a first surface and a second surface opposite the first surface, and in which an opening portion is formed; an imaging element which has a third surface and a fourth surface opposite the third surface, and which has a light receiver on the third-surface side and is positioned in the opening portion in such a way that the third surface faces in the same direction as the first surface; and an insulation layer formed on the first surface of the substrate in such a way to expose the light receiver of the imaging element. In such a wiring board, a hole penetrating through the insulation layer and reaching the light receiver of the imaging element is formed in the insulation layer, and a portion corresponding to the hole is made thinner than its surroundings on the second-surface side surface.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board with a built-in imaging element, comprising:
a substrate having an accommodation portion and a first surface and a second surface on an opposite side of the first surface;
an imaging device having a light receiver and positioned in the accommodation portion of the substrate such that the light receiver faces the first surface of the substrate;
a plurality of first insulation layers having an opening portion and formed on the first surface of the substrate such that the light receiver of the imaging device is exposed from the opening portion of the first insulation layers; and
a plurality of second insulation layers formed on the second surface of the substrate,
wherein the plurality of first insulation layers includes a first insulation layer, the plurality of second insulation layers includes a second insulation layer, the second insulation layer of the second insulation layers is positioned at a predetermined tier counted from the substrate and has a thermal expansion coefficient which is set lower than a thermal expansion coefficient of the first insulation layer of the first insulation layers positioned at a predetermined tier counted from the substrate such that imbalance in thermal expansion and thermal contraction between the plurality of first insulation layers and the plurality of second insulation layers is substantially offset or mitigated.

2. The wiring board with a built-in imaging element according to claim 1, wherein the thermal expansion coefficients of the first insulation layer and second insulation layer are thermal expansion coefficients of the first insulation layer and second insulation layer in an XY direction in a temperature range at or lower than a glass transition temperatures of the first insulation layer and second insulation layer.

3. The wiring board with a built-in imaging element according to claim 1, wherein the plurality of first insulation layers and the plurality of second insulation layers have a same number of layers.

4. The wiring board with a built-in imaging element according to claim 1, wherein each of the second insulation layers has a thermal expansion coefficient which is lower than a thermal expansion coefficient of each of the first insulation layers at each tier counted from the substrate.

5. The wiring board with a built-in imaging element according to claim 1, wherein the plurality of first insulation layers extends on a surface of the imaging device such that the opening portion of the first insulation layers exposes the light receiver of the imaging device.

6. The wiring board with a built-in imaging element according to claim 1, further comprising a plane conductor layer formed over a region corresponding to the opening portion of the plurality of first insulation layers on a second-surface side of the substrate.

7. The wiring board with a built-in imaging element according to claim 1, wherein each of the first and second insulation layers comprises a resin and a core material.

8. A wiring board with a built-in imaging element, comprising:
a substrate having an accommodation portion and a first surface and a second surface on an opposite side of the first surface;
an imaging device having a light receiver and positioned in the accommodation portion of the substrate such that the light receiver faces the first surface of the substrate;
a plurality of first insulation layers having an opening portion and formed on the first surface of the substrate such that the light receiver of the imaging device is exposed from the opening portion of the first insulation layers; and
a plurality of second insulation layers formed on the second surface of the substrate,
wherein the plurality of first insulation layers includes a first insulation layer, the plurality of second insulation layers includes a second insulation layer, the second insulation layer of the second insulation layers is positioned at a predetermined tier counted from the substrate and has a thickness which is set less than a thickness of the first insulation layer of the first insulation layers positioned at a predetermined tier counted from the substrate such that imbalance in thermal expansion and thermal contraction between the plurality of first insulation layers and the plurality of second insulation layers is substantially offset or mitigated.

9. The wiring board with a built-in imaging element according to claim 8, wherein the plurality of second insulation layers has a sum of thicknesses which is less than a sum of thicknesses of the plurality of first insulation layers.

10. The wiring board with a built-in imaging element according to claim 8, wherein the plurality of first insulation layers extends on a surface of the imaging device such that the opening portion of the first insulation layers exposes the light receiver of the imaging device.

11. The wiring board with a built-in imaging element according to claim 8, further comprising a plane conductor layer formed over a region corresponding to the opening portion of the plurality of first insulation layers on a second-surface side of the substrate.

12. The wiring board with a built-in imaging element according to claim 8, wherein each of the first and second insulation layers comprises a resin and a core material.

13. A wiring board with a built-in imaging element, comprising:
a substrate having an accommodation portion and a first surface and a second surface on an opposite side of the first surface;
an imaging device having a light receiver and positioned in the accommodation portion of the substrate such that the light receiver faces the first surface of the substrate;
a plurality of first insulation layers having an opening portion and formed on the first surface of the substrate such that the light receiver of the imaging device is exposed from the opening portion of the first insulation layers; and
a plurality of second insulation layers formed on the second surface of the substrate,
wherein the plurality of second insulation layers has a number of layers which is less than a number of layers of the plurality of first insulation layers such that imbalance in thermal expansion and thermal contraction between the plurality of first insulation layers and the plurality of second insulation layers is substantially offset or mitigated.

14. A wiring board with a built-in imaging element, comprising
a substrate having an accommodation portion and a first surface and a second surface on an opposite side of the first surface;
an imaging device having a light receiver and positioned in the accommodation portion of the substrate such that the light receiver faces the first surface of the substrate;
a plurality of first insulation layers having an opening portion and formed on the first surface of the substrate such that the light receiver of the imaging device is exposed from the opening portion of the first insulation layers; and
a plurality of second insulation layers formed on the second surface of the substrate,
wherein the plurality of second insulation layers has a thinned portion in a region corresponding to the opening portion of the plurality of first insulation layers, and the thinned portion of the plurality of second insulation layers has a thickness which is sufficiently thinned such that imbalance in thermal expansion and thermal contraction between the plurality of first insulation layers and the plurality of second insulation layers is substantially offset or mitigated.

15. The wiring board with a built-in imaging element according to claim 14, further comprising a solder resist layer formed on a surface of the imaging device on a second surface side of the substrate, wherein the solder resist layer has a portion which made thinner or removed in a region corresponding to the opening portion of the plurality of first insulation layers.

16. The wiring board with a built-in imaging element according to claim 14, wherein the plurality of first insulation layers extends on a surface of the imaging device such that the opening portion of the first insulation layers exposes the light receiver of the imaging device.

17. The wiring board with a built-in imaging element according to claim 14, further comprising a plane conductor layer formed over a region corresponding to the opening portion of the plurality of first insulation layers on a second-surface side of the substrate.

18. The wiring board with a built-in imaging element according to claim 14, wherein each of the first and second insulation layers comprises a resin and a core material.
